(19) United States
(12) Patent Application Publication
(10) Pub. No.: US 2026/0231475 A1
(43) Pub. Date: Aug. 6, 2026

(54) SEMICONDUCTOR DEVICE

(71) Applicant: SEMICONDUCTOR ENERGY LABORATORY CO., LTD., Atsugi-shi, Kanagawa-ken (JP)

(72) Inventors: Yoshiyuki KUROKAWA, Sagamihara, Kanagawa (JP); Hiromichi GODO, Isehara, Kanagawa (JP); Yuto YAKUBO, Atsugi, Kanagawa (JP); Satoru OHSHITA, Hadano, Kanagawa (JP)

(21) Appl. No.: 18/855,861

(22) PCT Filed: Apr. 17, 2023
(86) PCT No.: PCT/IB2023/053891

§ 371 Date: Oct. 10, 2024

(30) Foreign Application Priority Data
Apr. 29, 2022 (JP) 2022-075540

(51) Int. Cl. H10D 30/67; G11C 11/4076; G11C 11/417; H10B 10/00; H10B 12/00; H10B 80/00; H10D 80/30; H10W 90/00; H10W 90/20

(52) U.S. Cl. CPC H10D 30/6755; G11C 11/4076; G11C 11/417; H10W 90/297; H10B 10/125; H10B 12/31; H10B 80/00; H10D 30/6734; H10D 80/30; H10W 90/722; H10W 90/7295; H10W 90/792

(57) ABSTRACT

A semiconductor device with a novel structure is provided. The semiconductor device includes a base die provided with a clock signal generation circuit and a first synchronous circuit and a plurality of dies provided to be stacked over the base die. The base die and the plurality of dies are electrically connected to each other via through electrodes provided in the plurality of dies. The plurality of dies each include a second synchronous circuit. The clock signal generation circuit has a function of generating a plurality of clock signals with different frequencies. The second synchronous circuit is a circuit operating by an input of any one of the clock signals with different frequencies to each of the plurality of dies. The clock signals with different frequencies are supplied to the second synchronous circuits included in the plurality of dies via the through electrodes.

### TECHNICAL FIELD

One embodiment of the present invention relates to a semiconductor device and the like.

Note that one embodiment of the present invention is not limited to the above technical field. The technical field of the invention disclosed in this specification and the like relates to an object, a method, or a manufacturing method. Alternatively, one embodiment of the present invention relates to a process, a machine, manufacture, or a composition of matter. Thus, more specifically, examples of the technical field of one embodiment of the present invention disclosed in this specification include a semiconductor device, a display apparatus, a light-emitting apparatus, a power storage device, a memory device, a driving method thereof, and a manufacturing method thereof.

### BACKGROUND ART

Electronic devices including electronic circuits (also simply referred to as circuits) have been widely used. The circuits are roughly classified into a synchronous circuit that operates in synchronization with a clock signal and an asynchronous circuit that does not use a clock signal. Many of logic circuits such as a CPU (Central Processing Unit) and a GPU (Graphics Processing Unit) include synchronous circuits. In addition, input/output circuits in memory devices include synchronous circuits.

In a synchronous circuit, a flip-flop is driven by a clock signal, and in general, data in the flip-flop is updated in response to the rising edge of the clock signal. When data in a plurality of flip-flops included in the synchronous circuit are repeatedly updated at the same time, processing in the synchronous circuit can proceed. Thus, matching the timings of the clock signals supplied to the flip-flops in the synchronous circuit is an important limitation condition in designing the synchronous circuit.

In recent years, active research and development have been conducted on a structure in which dies (e.g., Si dies) provided with memories such as SRAM cells or DRAM cells are stacked three-dimensionally (e.g., Non-Patent Document 1 and Non-Patent Document 2).

### REFERENCES

[Non-Patent Document 1] T. Burd et al., ISSCC Dig. Tech. Papers, pp. 54-55, 2022.
[Non-Patent Document 2] J. Wuu et al., ISSCC Dig. Tech. Papers, pp. 428-429, 2022.

### SUMMARY OF THE INVENTION

### Problems to Be Solved by the Invention

In a semiconductor device including a plurality of synchronous circuits, timings of clock signals need to be matched between the synchronous circuits. However, when the circuit scale is increased by three-dimensional stacking of dies, for example, it becomes difficult to distribute clock signals to all the synchronous circuits and to match the timings of the clock signals.

Since clock signals with a single frequency are not necessarily used in all the synchronous circuits, some of the synchronous circuits may be driven by clock signals with a low frequency to reduce power consumption. In the case of this structure, a clock signal with a low frequency preferably maintains synchronism with the original clock signal, such as the specified fraction of the integer (1/N) or an integer/integer multiple (MIN) of the original clock signal (M and N are each an integer). In the case of a structure using independent asynchronous clock signals, data transmission and reception between synchronous circuits driven by clock signals with different frequencies need to be performed via a special interface such as a FIFO (First In First Out) method or a handshake method.

As described above, in the semiconductor device in which clock signals with different frequencies are used in the plurality of synchronous circuits, the clock signals with different frequencies are preferably generated on the basis of the clock signals with a single frequency in a clock signal generation circuit. However, the clock signals with different frequencies need to be distributed from the clock signal generation circuit to the synchronous circuits; accordingly, as a wiring electrically connecting the clock signal generation circuit and the synchronous circuits becomes longer, power consumption required for charging and discharging of the wiring may be increased.

In addition, when the timings of clock signals distributed to the synchronous circuits become difficult to match, a wiring layer in an upper layer needs to be used for an interface such as the FIFO method or the handshake method; accordingly, a wiring for electrically connecting the synchronous circuits becomes complicated. Thus, it may be difficult to provide an element such as a transistor in the wiring layer in an upper layer.

One object of one embodiment of the present invention is to provide a semiconductor device having a novel structure in which low-latency clock signals can be supplied to synchronous circuits in layers in a structure where a plurality of dies provided with the synchronous circuits are three-dimensionally stacked. Another object of one embodiment of the present invention is to provide a semiconductor device having a novel structure that facilitates matching of timings of clock signals in a structure where a plurality of dies provided with synchronous circuits are three-dimensionally stacked. Another object of one embodiment of the present invention is to provide a semiconductor device that can reduce power consumption by suppressing an increase in power consumed by a clock signal distribution in a structure where a plurality of dies provided with synchronous circuits are three-dimensionally stacked. Another object of one embodiment of the present invention is to provide a semiconductor device having a novel structure.

Note that the objects of one embodiment of the present invention are not limited to the objects listed above. The objects listed above do not preclude the existence of other objects. Note that the other objects are objects that are not described in this section and will be described below. The objects that are not described in this section are derived from the description of the specification, the drawings, and the like and can be extracted as appropriate from the description by those skilled in the art. Note that one embodiment of the present invention is to achieve at least one of the objects listed above and/or the other objects.

### Means for Solving the Problems

One embodiment of the present invention is a semiconductor device including a base die provided with a clock signal generation circuit and a first synchronous circuit and a plurality of dies provided to be stacked over the base die, in which the base die and the plurality of dies are electrically connected to each other via through electrodes provided in the plurality of dies; the plurality of dies each include a second synchronous circuit; the clock signal generation circuit has a function of generating a plurality of clock signals with different frequencies; the second synchronous circuit is a circuit operating by an input of any one of the clock signals with different frequencies to each of the plurality of dies; and the clock signals with different frequencies are supplied to the second synchronous circuits included in the plurality of dies via the through electrodes.

In the semiconductor device of one embodiment of the present invention, preferably, the first synchronous circuit is a CPU.

In the semiconductor device of one embodiment of the present invention, preferably, the plurality of clock signals with different frequencies are signals generated on the basis of a reference frequency.

In the semiconductor device of one embodiment of the present invention, preferably, a frequency of a clock signal supplied to the second synchronous circuit is lower than a frequency of a clock signal supplied to the first synchronous circuit.

In the semiconductor device of one embodiment of the present invention, preferably, the through electrodes are electrically connected to each other via a metal bump provided between the plurality of dies.

In the semiconductor device of one embodiment of the present invention, preferably, the second synchronous circuit includes a transistor including an oxide semiconductor in a channel formation region.

In the semiconductor device of one embodiment of the present invention, preferably, layers each including the transistor are provided to be stacked.

In one embodiment of the present invention, preferably, the oxide semiconductor includes In, Ga, and Zn.

Note that other embodiments of the present invention are shown in the description of the following embodiments and the drawings.

### Effect of the Invention

One embodiment of the present invention can provide a semiconductor device having a novel structure in which low-latency clock signals can be supplied to synchronous circuits in layers in a structure where a plurality of dies provided with the synchronous circuits are three-dimensionally stacked. Another embodiment of the present invention can provide a semiconductor device having a novel structure that facilitates matching of timings of clock signals in a structure where a plurality of dies provided with synchronous circuits are three-dimensionally stacked. Another embodiment of the present invention can provide a semiconductor device that can reduce power consumption by suppressing an increase in power consumed by a clock signal distribution in a structure where a plurality of dies provided with synchronous circuits are three-dimensionally stacked. Another embodiment of the present invention can provide a semiconductor device having a novel structure.

Note that the description of these effects does not preclude the existence of other effects. Note that one embodiment of the present invention does not need to have all these effects. Note that effects other than these will be apparent from the description of the specification, the drawings, the claims, and the like and effects other than these can be derived from the description of the specification, the drawings, the claims, and the like.

### BRIEF DESCRIPTION OF THE DRAWINGS

FIG. 1 is a diagram illustrating a structure example of a semiconductor device.

FIG. 2 is a diagram illustrating a structure example of a semiconductor device.

FIG. 3A and FIG. 3B are diagrams illustrating a structure example of a semiconductor device.

FIG. 4A and FIG. 4B are diagrams each illustrating a structure example of a semiconductor device.

FIG. 5 is a diagram illustrating a structure example of a semiconductor device.

FIG. 6A and FIG. 6B are diagrams illustrating a structure example of a semiconductor device.

FIG. 7A to FIG. 7D are diagrams each illustrating a structure example of a semiconductor device.

FIG. 8 is a diagram illustrating a structure example of a semiconductor device.

FIG. 9A to FIG. 9C are diagrams illustrating a structure example of a semiconductor device.

FIG. 10 is a diagram illustrating a structure example of a memory portion.

FIG. 11A is a diagram illustrating a structure example of a memory layer. FIG. 11B is a diagram illustrating an equivalent circuit of the memory layer.

FIG. 12 is a diagram illustrating a structure example of a memory portion.

FIG. 13A is a diagram illustrating a structure example of a memory layer. FIG. 13B is a diagram illustrating an equivalent circuit in the memory layer.

FIG. 14A and FIG. 14B are diagrams each illustrating an example of an electronic component.

FIG. 15A and FIG. 15B are diagrams each illustrating an example of an electronic device, and FIG. 15C to FIG. 15E are diagrams illustrating an example of a large computer.

FIG. 16 is a diagram illustrating an example of a device for space.

FIG. 17 is a diagram illustrating an example of a storage system that can be used in a data center.

### MODE FOR CARRYING OUT THE INVENTION

Embodiments will be described below with reference to the drawings. Note that the embodiments can be implemented with many different modes, and it will be readily understood by those skilled in the art that modes and details thereof can be changed in various ways without departing from the spirit and scope thereof. Thus, the present invention should not be construed as being limited to the description of embodiments below.

In addition, in the drawings, the size, the layer thickness, or the region is exaggerated for clarity in some cases. Thus, the size, the layer thickness, or the region is not limited to the illustrated scale. Note that the drawings schematically illustrate ideal examples, and embodiments of the present invention are not limited to shapes, values, and the like illustrated in the drawings.

Furthermore, unless otherwise specified, off-state current in this specification and the like refers to drain current of a transistor in an off state (also referred to as a non-conduction state or a cutoff state). Unless otherwise specified, an off state in an n-channel transistor refers to a state where voltage V_{gs} between its gate and source is lower than threshold voltage Vₜₕ (in a p-channel transistor, higher than Vₜₕ).

In this specification and the like, a metal oxide is an oxide of a metal in a broad sense. Metal oxides are classified into an oxide insulator, an oxide conductor (including a transparent oxide conductor), an oxide semiconductor (also simply referred to as an OS), and the like. For example, in the case where a metal oxide is used for an active layer of a transistor, the metal oxide is referred to as an oxide semiconductor in some cases. That is, an OS transistor can also be referred to as a transistor including a metal oxide or an oxide semiconductor.

### Embodiment 1

In this embodiment, structure examples of a semiconductor device will be described. A semiconductor device described in one embodiment of the present invention functions as an SoC (System on a chip) including a plurality of synchronous circuits such as a memory and a peripheral circuit, in addition to a CPU and a cache memory.

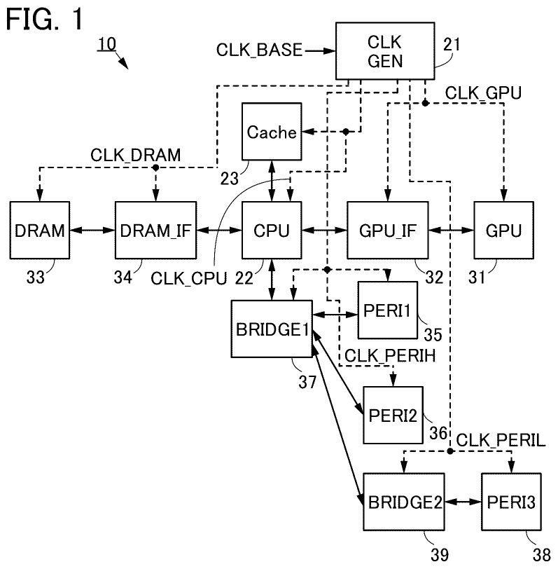

FIG. 1A is a block diagram illustrating the semiconductor device of one embodiment of the present invention.

The semiconductor device includes a plurality of synchronous circuits that are driven by clock signals with different frequencies output from a clock signal generation circuit.

A semiconductor device 10 illustrated in FIG. 1 includes, for example, a clock signal generation circuit 21 (denoted by CLKGEN in the drawing), a CPU 22, a cache memory 23 (denoted by Cache in the drawing), a GPU 31, an interface 32 (denoted by GPU_IF in the drawing), a main memory 33 (denoted by DRAM in the drawing), an interface 34 (denoted by DRAM_IF in the drawing), a peripheral circuit 35 (denoted by PERII in the drawing), a peripheral circuit 36 (denoted by PERI2 in the drawing), a bridge circuit 37 (denoted by BRIDGE1 in the drawing), a peripheral circuit 38 (denoted by PERI3 in the drawing), and a bridge circuit 39 (denoted by BRIDGE2). Data signals input and output between circuits are indicated by solid arrows in FIG. 1.

The clock signal generation circuit 21, the CPU 22, the cache memory 23, the GPU 31, the interface 32, the main memory 33, the interface 34, the peripheral circuits 35 and 36, the bridge circuit 37, the peripheral circuit 38, and the bridge circuit 39 are synchronous circuits. Thus, the clock signal generation circuit 21 preferably generates clock signals with different frequencies on the basis of clock signals with a single frequency and outputs the clock signals to the synchronous circuits.

The clock signal generation circuit 21 generates a clock signal CLK_CPU supplied from a reference clock signal CLK_BASE to the CPU 22. The clock signal generation circuit 21 generates a clock signal CLK_GPU supplied from the reference clock signal CLK_BASE to the GPU 31. The clock signal generation circuit 21 generates a clock signal CLK_DRAM supplied from the reference clock signal CLK_BASE to the main memory 33. The clock signal generation circuit 21 generates a clock signal CLK_PERIH supplied from the reference clock signal CLK_BASE to the peripheral circuit 35 and the peripheral circuit 36. The clock signal generation circuit 21 generates a clock signal CLK_PERIL supplied from the reference clock signal CLK BASE to the peripheral circuit 38. The clock signals generated in the clock signal generation circuit 21 are indicated by dashed arrows in FIG. 1.

A plurality of clock signals (the CLK_CPU, the CLK_GPU, the CLK_DRAM, the CLK_PERIH, and the CLK_PERIL) can be generated as clock signals with different frequencies on the basis of the reference clock signal CLK_BASE.

For example, the clock signal CLK_CPU is generated by multiplying the reference clock signal CLK_BASE (by multiplying the input frequency by N) and is output as a clock signal with a high frequency. The clock signal CLK_GPU is the same as the clock signal CLK_CPU or is generated by dividing the frequency of the clock signal CLK_CPU, and is output as a clock signal with a high frequency. The clock signal CLK_DRAM is generated by dividing the frequency of the clock signal CLK_CPU and output as a clock signal with a frequency corresponding to an operation frequency of the main memory 33. The clock signal CLK_PERIH is generated by dividing the frequency of the clock signal CLK_CPU and output as a clock signal with a frequency in accordance with operation frequencies of the peripheral circuits 35 and 36. The clock signal CLK_PERIL is generated by dividing the frequency of the clock signal CLK_CPU and output as a clock signal with a frequency corresponding to an operation frequency of the peripheral circuit 38, which is lower than the operation frequencies of the peripheral circuits 35 and 36.

The CPU 22 is driven by the clock signal CLK_CPU. The CPU 22 has a function of executing arithmetic processing as a main arithmetic portion of the semiconductor device 10. The CPU 22 is a circuit that performs arithmetic processing such as logic operation or address operation in accordance with an input signal or data. The CPU 22 is also referred to as an arithmetic portion, a signal processing circuit, or a CPU core in some cases.

The cache memory 23 is driven by the clock signal CLK_CPU. The cache memory 23 has a function of storing a program or data necessary for arithmetic processing of the CPU 22. A cache memory is a circuit having a function of temporarily storing information on a signal or the like corresponding to a calculation result obtained by arithmetic processing of the CPU 22 to increase the data processing speed. In the case where a primary cache is provided in the CPU 22, for example, the cache memory 23 placed at a position close to the CPU 22 can be used as a secondary cache.

The GPU 31 is driven by the clock signal CLK_GPU. The GPU 31 has a function of executing arithmetic processing necessary for drawing an image, for example. Without limitation to image drawing, the GPU 31 can execute arithmetic processing such as product-sum operation processing.

The interface 32 is driven by the clock signal CLK_GPU. The interface 32 is a circuit having a function of performing data transmission and reception between the CPU 22 and the GPU 31.

The main memory 33 is driven by the clock signal CLK_DRAM. The main memory 33 has a function of storing data necessary for arithmetic processing of the CPU 22 or the GPU 31. As the main memory 33, a DRAM or a memory including an OS transistor described in a subsequent embodiment can be used. The main memory 33 placed at a position close to the CPU 22 can be used as a tertiary cache.

The interface 34 is driven by the clock signal CLK_DRAM. The interface 34 is a circuit having a function of performing data transmission and reception between the CPU 22 and the main memory 33.

The peripheral circuits 35 and 36 are driven by the clock signal CLK PERIH. The peripheral circuits 35 and 36 are peripheral circuits necessary for relatively high-speed processing. Examples of the peripheral circuits 35 and 36 include main memories different from the main memory 33 and a PCI (Peripheral Component Interconnect).

The peripheral circuit 38 is driven by the clock signal CLK_PERIL. The peripheral circuit 38 is a peripheral circuit necessary for relatively low-speed processing. Examples of the peripheral circuit 38 include a LAN (Local Area Network), a USB (Universal Serial Bus), and the like.

The bridge circuit 37 is driven by the clock signal CLK_PERIH. The bridge circuit 37 is a circuit serving as a system controller that performs data transmission and reception between the CPU 22 and the peripheral circuits 35 and 36. The bridge circuit 39 is driven by the clock signal CLK_PERIL. The bridge circuit 39 is a circuit serving as a system controller that performs data transmission and reception between the bridge circuit 37 and the peripheral circuit 38.

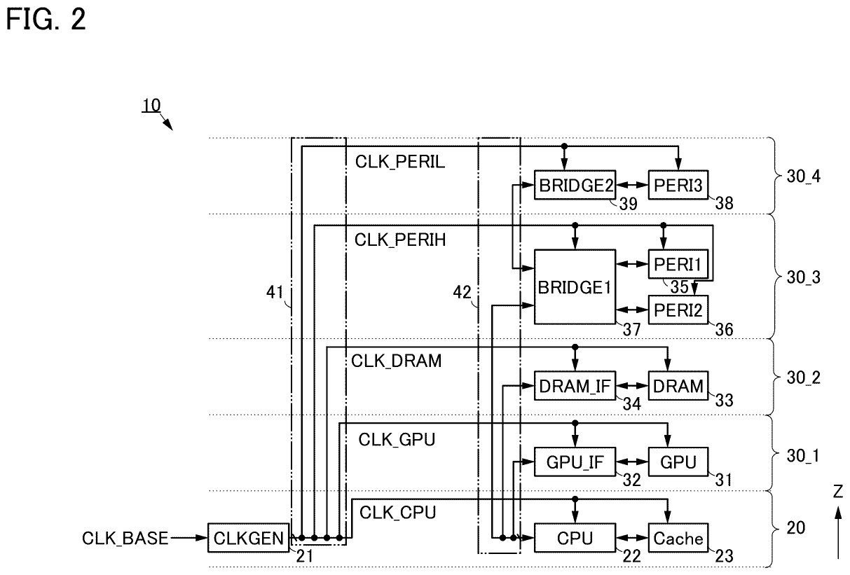

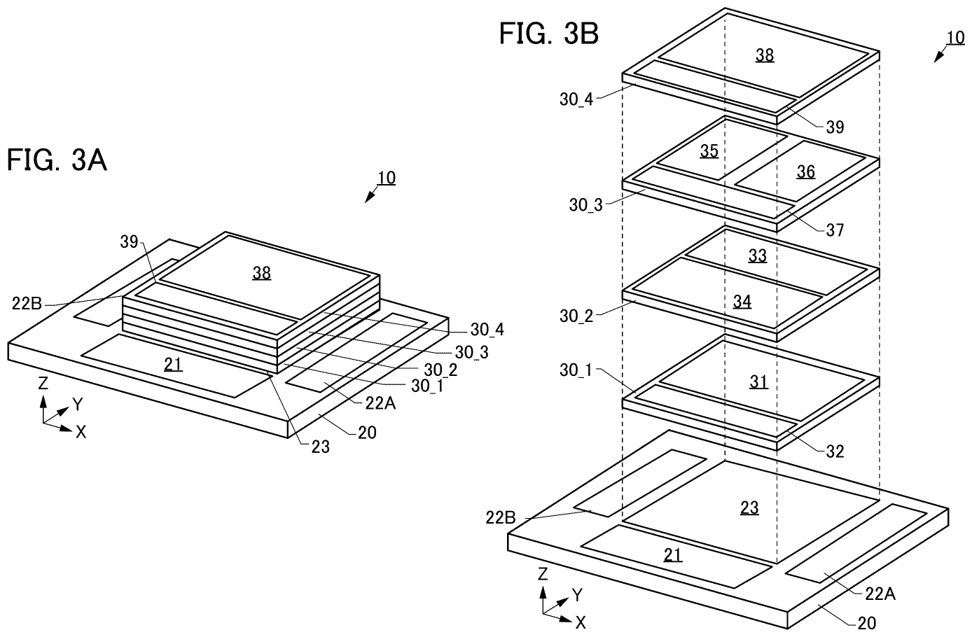

FIG. 2 illustrates the semiconductor device 10 in FIG. 1 having a structure in which the synchronous circuits supplied with the plurality of clock signals (the CLK_CPU, the CLK_GPU, the CLK_DRAM, the CLK_PERIH, and the CLK_PERIL) are provided in a plurality of different dies, and the plurality of dies are stacked over a base die. FIG. 3A is a diagram illustrating an example of a perspective view corresponding to the structure in FIG. 2. FIG. 3B is a perspective view of the structure in FIG. 3A, which illustrates different dies apart from each other.

FIG. 2, FIG. 3A, and FIG. 3B each illustrate a base die 20 provided with the clock signal generation circuit 21, the CPU 22, and the like and dies 30_1 to 30_4 stacked over the base die 20, for example. Note that FIG. 2 is a schematic view of a cross section where the base die 20 and the dies 30_1 to 30_4 are stacked. The Z direction in FIG. 2 represents a direction perpendicular to the surface of the base die 20 (a plane represented by the X direction and the Y direction) or a direction in which the dies 30_1 to 30_4 are provided to be stacked over the base die 20.

Note that FIG. 2 illustrates a case where the CPU 22 functioning as a CPU core is a single core. In this case, one CPU core is included in the semiconductor device 10, but a multicore structure including a plurality of CPU cores can also be employed. For example, FIG. 3A and FIG. 3B each illustrate CPUs 22A and 22B functioning as CPU cores.

Note that in FIG. 3A and FIG. 3B, the dies 30_1 to 30_4 are provided in a region not overlapping with a region where the CPUs 22A and 22B included in the base die 20 are provided. For example, the dies 30_1 to 30_4 are provided in a region overlapping with a region where the cache memory 23 is provided. With this structure, the influence of heat generation of the CPUs 22A and 22B on the dies 30_1 to 30_4 can be reduced.

The base die 20 includes the clock signal generation circuit 21, the CPU 22 (the CPUs 22A and 22B), and the cache memory 23. As illustrated in FIG. 2, the base die 20 is provided with the CPU 22 and the cache memory 23, which are synchronous circuits driven by the clock signal CLK_CPU, in addition to the clock signal generation circuit 21 that generates a plurality of clock signals on the basis of the reference clock signal CLK BASE. The base die 20 and the dies 30_1 to 30_4 described later may be referred to as element layers or layers. In addition, a synchronous circuit such as the CPU 22 included in the base die 20 is referred to as a first synchronous circuit in some cases. Note that in this specification and the like, a base die is a die that has a larger size than other dies and is placed in the lowest layer of stacked dies. The base die is referred to as a base tile or the like in some cases.

The die 30_1 includes the GPU 31 and the interface 32. As illustrated in FIG. 2, the die 30_1 is provided with the GPU 31 and the interface 32 which are synchronous circuits driven by the clock signal CLK_GPU. The GPU 31 can input and output data to and from the CPU 22 or the like included in the base die 20 via the interface 32.

The die 30_2 includes the main memory 33 and the interface 34. As illustrated in FIG. 2, the die 30_2 is provided with the main memory 33 and the interface 34 which are synchronous circuits driven by the clock signal CLK_DRAM. The main memory 33 can input and output data to and from the CPU 22 or the like included in the base die 20 via the interface 34.

The die 30_3 includes the peripheral circuits 35 and 36 and the bridge circuit 37. As illustrated in FIG. 2, the die 30_3 is provided with the peripheral circuits 35 and 36 and the bridge circuit 37 which are synchronous circuits driven by the clock signal CLK PERIH. The peripheral circuits 35 and 36 can input and output data to and from the CPU 22 or the like included in the base die 20 via the bridge circuit 37.

The die 30_4 includes the peripheral circuit 38 and the bridge circuit 39. As illustrated in FIG. 2, the die 30_4 is provided with the peripheral circuit 38 and the bridge circuit 39 which are synchronous circuits driven by the clock signal CLK_PERIL. The peripheral circuit 38 can input and output data to and from the CPU 22 or the like included in the base die 20 via the bridge circuits 37 and 39.

In addition, the synchronous circuit such as the GPU 31 included in the die 30_1, the synchronous circuit such as the main memory 33 included in the die 30_2, the synchronous circuits such as the peripheral circuits 35 and 36 included in the die 30_3, and the synchronous circuit such as the peripheral circuit 38 included in the die 30_4 are each referred to as a second synchronous circuit in some cases.

FIG. 2, FIG. 3A, and FIG. 3B illustrate a state where the dies 30_1 to 30_4 are provided to be stacked over the base die 20 in the semiconductor device 10. Providing a plurality of dies (e.g., (n-1) layers (n is an integer greater than or equal to 2)) over the base die 20 can reduce the area occupied by the semiconductor device 10. Furthermore, when the main memory 33 and the like have a structure in which a plurality of dies or a plurality of element layers are stacked, the storage capacity per unit area can be increased.

In FIG. 2, FIG. 3A, and FIG. 3B, the first layer is denoted as the base die 20, and the dies provided to be stacked over the base die 20 are denoted by the dies 30_1 to 30_4. Among the dies provided to be stacked over the base die 20, a die in an n-th layer can be referred to as, for example, a die 30_n. The die 30_n is referred to as an n-th die in some cases. Note that in this embodiment and the like, the “die 30” is merely stated in some cases when describing a matter related to all the n layers of dies formed of the dies 30_1 to 30_n or when showing a matter common to the layers of the dies 30.

The base die 20 and the dies 30_1 to 30_4 each include a transistor in which a semiconductor layer including a channel formation region includes silicon (a Si transistor). The Si transistor enables a structure for forming a synchronous circuit using a CMOS circuit (a Si CMOS circuit). With this structure, a synchronous circuit of the Si CMOS circuit can be provided in each layer. Each synchronous circuit can be formed with the CMOS circuit, which enables high-speed operation.

Note that for the semiconductor layer including a channel formation region of the Si transistor, a single crystal semiconductor, a polycrystalline semiconductor, a microcrystalline semiconductor, an amorphous semiconductor, or the like can be used alone or in combination. A semiconductor material is not limited to silicon and can be germanium or the like, for example. Alternatively, a compound semiconductor such as silicon germanium, silicon carbide, gallium arsenide, or a nitride semiconductor may be used.

The base die 20 and the dies 30_1 to 30_4 including Si transistors can be stacked element layers where the substrates are connected to each other with a technique using a through electrode such as a TSV (Through Silicon Via), a Cu—Cu (copper-copper) direct bonding technique (a technique for achieving electrical continuity by connecting Cu (copper) pads), or the like.

In FIG. 2, the plurality of clock signals (the CLK_CPU, the CLK_GPU, the CLK_DRAM, the CLK_PERIH, and the CLK_PERIL) output to the plurality of synchronous circuits included in the dies 30_1 to 30_4, which are provided to be stacked over the base die 20, are supplied to the synchronous circuits provided in the dies 30_1 to 30_4 via through electrodes 41 provided in the base die 20 and the dies 30_1 to 30_4 and via metal bumps provided between the dies. The through electrodes 41 are separately provided in accordance with paths through which the plurality of clock signals are transmitted. The through electrodes 41 are electrodes provided to penetrate the dies to electrically connect the top surfaces and the bottom surfaces of the dies. In addition, input and output of data between the CPU 22 included in the base die 20 and the synchronous circuits provided in the dies 30_1 to 30_4 are performed via through electrodes 42 provided in the base die 20 and the dies 30_1 to 30_4. The through electrodes 42 are separately provided in accordance with transmission paths of data signals between the CPU 22 and the synchronous circuits provided in the dies 30_1 to 30_4.

Note that in the plurality of dies 30_1 to 30_n provided to be stacked over the base die 20, the frequency of a clock signal supplied to the synchronous circuit included in the die 30_n (the die 30_4 in the example of FIG. 2) provided in the upper layer is preferably lower than the frequency of a clock signal supplied to the synchronous circuit included in the base die 20. In the case where the logic circuit included in the CPU 22 supplied with a clock signal with a high frequency is placed close to the clock signal generation circuit 21 and the synchronous circuit supplied with a clock signal with a low frequency is placed in an upper layer, timing adjustment of the clock signals can be easy, and power consumption necessary for the clock signal distribution can be reduced.

In one embodiment of the present invention, the clock signals generated in the clock signal generation circuit 21 included in the base die 20 are distributed via through electrodes such as a TSV and metal bumps. With such a structure, the clock signals and the like can be distributed via wirings inside the dies. In addition, timing adjustment of the clock signals to be distributed to the synchronous circuits can be easily performed.

In addition, since a wiring for the clock signal input to the synchronous circuit is laid out using a wiring layer that is an upper layer of the synchronous circuit, the use of the wiring layer that is an upper layer in each die can be decreased when the synchronous circuits driven by clock signals with different frequencies are separately provided in a plurality of dies. This facilitates employing a structure in which OS transistors and the like are provided in the wiring layer positioned in an upper layer of the synchronous circuit, and thus, normally-off operation can be performed with the use of OS transistors in the CPU 22, the GPU 31, and the peripheral circuits 35, 36, and 38. Furthermore, the DRAM applicable to the main memory can be easily changed into a memory using an OS transistor, so that power consumption can be reduced by utilizing the characteristics of extremely low off-state current of the OS transistor.

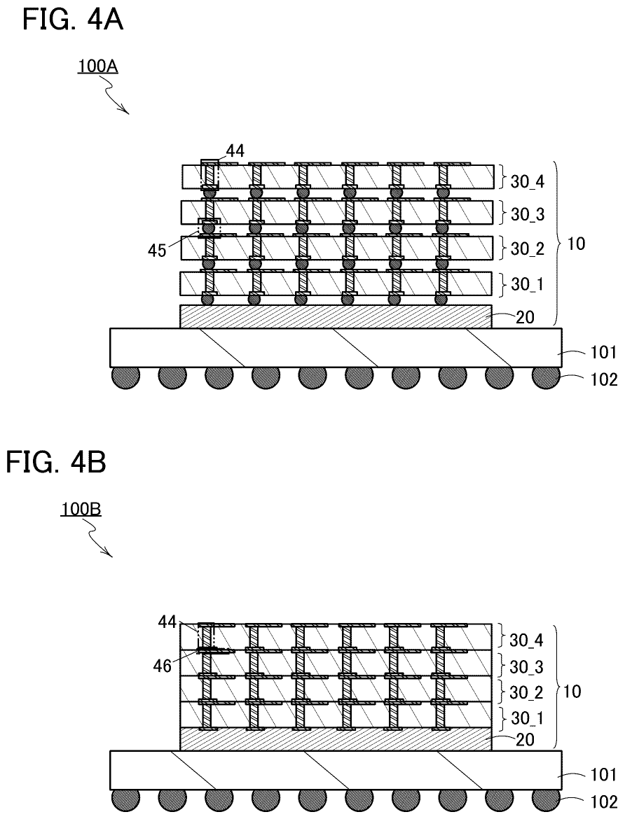

FIG. 4A and FIG. 4B illustrate examples of an integrated circuit (referred to as an IC chip) including the above-described semiconductor device 10. The semiconductor device 10 can be one IC chip by mounting a plurality of dies on a packaging substrate. FIG. 4A and FIG. 4B illustrate an example of the structure.

A schematic cross-sectional view of an IC chip 100A illustrated in FIG. 4A illustrates the semiconductor device 10 in which the base die 20 is provided over a package substrate 101 and four layers of the dies 30_1 to 30_4 are stacked over the base die 20, for example. Solder balls 102 for connecting the IC chip 100A to a printed circuit board or the like are provided on the package substrate 101. The dies 30_1 to 30_4 can be connected to the base die 20 via through electrodes 44 provided to penetrate the dies 30_1 to 30_4. In addition, the layers can be electrically connected to each other via the through electrodes 44 provided to penetrate the layers and metal bumps 45 (also referred to as micro-bumps) provided between the through electrodes 44.

For another example, in a schematic cross-sectional view of an IC chip 100B illustrated in FIG. 4B, the base die 20 is provided over the package substrate 101 and, for example, the four layers of the dies 30_1 to 30_4 are stacked over the base die 20. The through electrodes 44 are provided to penetrate the dies 30_1 to 30_4. The dies 30_1 to 30_4 are bonded to each other with electrodes 46 provided to be exposed on surfaces. As a technique for electrically bonding different layers using the electrode 46, Cu—Cu bonding can be used. The Cu—Cu bonding is a technique that establishes electrical continuity by connecting Cu (copper) pads.

As illustrated in FIG. 4A and FIG. 4B, in the case where the synchronous circuits driven by clock signals with different frequencies are provided in different dies and the dies are three-dimensionally stacked, element layers 30 are electrically connected to each other by a technique using a through electrode such as the TSV, the Cu—Cu direct bonding technique, or the like. With such a structure, clock signals and the like supplied to the dies can be distributed via wirings inside the dies. In addition, timing adjustment of the clock signals to be distributed to the synchronous circuits can be easily performed. Moreover, since a wiring for the clock signal input to the synchronous circuit is laid out using a wiring layer that is an upper layer of the synchronous circuit, the use of the wiring layer that is an upper layer in each die can be decreased when the synchronous circuits driven by clock signals with different frequencies are separately provided in a plurality of dies. This facilitates employing a structure in which OS transistors and the like are provided in the wiring layer, and thus, normally-off operation can be performed with the use of OS transistors in the CPU 22, the GPU 31, and the peripheral circuits 35, 36, and 38. Furthermore, the DRAM applicable to the main memory can be easily changed into a memory using an OS transistor, so that power consumption can be reduced by utilizing the characteristics of extremely low off-state current of the OS transistor.

This embodiment can be implemented in combination with the other embodiments described in this specification as appropriate.

### Embodiment 2

In this embodiment, a modification example of the semiconductor device described in the above embodiment is described. Note that components in common with those in Embodiment 1 are denoted by common reference numerals, and description thereof is omitted.

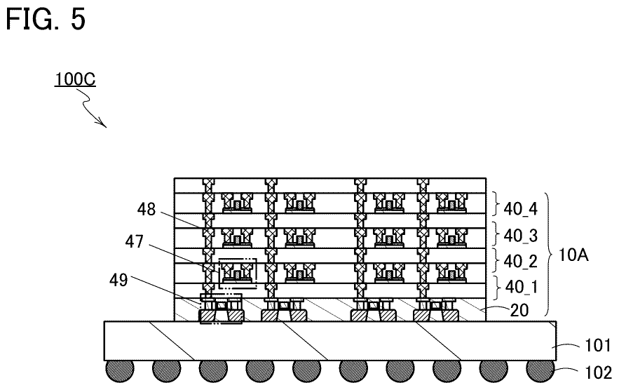

FIG. 5 is a schematic cross-sectional view for describing a semiconductor device that is different from the schematic cross-sectional view of the semiconductor device 10 mounted on the IC chip described with reference to each of FIG. 4A and FIG. 4B. In an IC chip 100C illustrated in FIG. 5, a semiconductor device 10A includes Si transistors 49 in the base die 20, and element layers 40 1 to 40_4 including OS transistors 47 are provided over an element layer including the Si transistors 49 in the base die 20. Electrodes 48 for electrically connecting the base die 20 and the element layers 40_1 to 40_4 can be provided in a step of manufacturing the Si transistors 49 or the OS transistors 47.

In FIG. 5, a structure of a connection between the base die 20 including the Si transistors 49 and the element layers 40_1 to 40_4 including the OS transistors can be a monolithic structure that does not use a technique using a through electrode such as a TSV or a Cu—Cu direct bonding technique. The element layers 40 1 to 40 4 over the base die 20 can have a structure in which wirings provided together with the OS transistors 47 included in the element layers 40_1 to 40_4 are used as the electrodes 48 for connecting the element layers in an upper layer and a lower layer.

The intervals between the wirings provided together with the OS transistors 47 can be smaller than those between through electrodes using a TSV or a Cu—Cu direct bonding technique. Accordingly, in the structure of the semiconductor device 10A illustrated in FIG. 5, the number of electrodes for connecting the element layers in the upper layer and the lower layer can be increased. Thus, the number of wirings (the number of signal lines) between the synchronous circuits provided in the element layers 40_1 to 40_4 and the CPUs 22 provided in the base die 20 can be increased. In other words, the number of channels between the CPUs 22 and the synchronous circuits can be increased. This can increase the transfer amount (bandwidth) of signal that is transmitted and received between the base die 20 and the element layers 40. The increase in the bandwidth can increase the amount of data transfer per unit time.

Examples of a metal oxide used in the OS transistors include indium oxide, gallium oxide, and zinc oxide. The metal oxide preferably includes two or three kinds selected from indium, an element M, and zinc. Note that the element M is one or more kinds selected from gallium, aluminum, silicon, boron, yttrium, tin, antimony, copper, vanadium, beryllium, titanium, iron, nickel, germanium, zirconium, molybdenum, lanthanum, cerium, neodymium, hafnium, tantalum, tungsten, and magnesium. Specifically, the element M is preferably one or more kinds selected from aluminum, gallium, yttrium, and tin.

It is particularly preferable to use an oxide including indium (In), gallium (Ga), and zinc (Zn) (also referred to as IGZO) for the metal oxide. Alternatively, it is preferable to use an oxide including indium, tin, and zinc (also referred to as ITZO). Further alternatively, it is preferable to use an oxide including indium, gallium, tin, and zinc. Further alternatively, it is preferable to use an oxide including indium (In), aluminum (Al), and zinc (Zn) (also referred to as IAZO). Further alternatively, it is preferable to use an oxide including indium (In), aluminum (Al), gallium (Ga), and zinc (Zn) (also referred to as IAGZO). Further alternatively, it is preferable to use an oxide including indium (In), gallium (Ga), zinc (Zn), and tin (Sn) (also referred to as IGZTO).

The metal oxide used in an OS transistor may include two or more metal oxide layers with different compositions. For example, a stacked-layer structure of a first metal oxide layer having In:M:Zn=1:3:4 [atomic ratio] or a composition in the neighborhood thereof and a second metal oxide layer having In:M:Zn=1:1:1 [atomic ratio] or a composition in the neighborhood thereof and being provided over the first metal oxide layer can be suitably employed.

Alternatively, a stacked-layer structure of one selected from indium oxide, indium gallium oxide, and IGZO, and one selected from IAZO, IAGZO, and ITZO may be employed, for example.

The metal oxide used in the OS transistors preferably has crystallinity. Examples of an oxide semiconductor having crystallinity include a CAAC (c-axis aligned crystalline)-OS and an nc (nanocrystalline)-OS. When the oxide semiconductor having crystallinity is used, the semiconductor device can have high reliability.

The OS transistor operates stably even in a high-temperature environment and has small variation in characteristics. For example, the off-state current hardly increases even in the high-temperature environment. Specifically, the off-state current hardly increases even at an environmental temperature higher than or equal to room temperature and lower than or equal to 200° C. Furthermore, the on-state current is unlikely to decrease even in the high-temperature environment. Thus, a memory cell that includes the OS transistor can operate stably and have high reliability even in the high-temperature environment.

A NOSRAM is preferable as a memory cell that can be used as the main memory 33 or the like in the element layer 40 including OS transistors. NOSRAM (registered trademark) is an abbreviation for “Nonvolatile Oxide Semiconductor Random Access Memory (RAM)”. The memory cells of the NOSRAM are two-transistor (2T) or three-transistor (3T) gain cells.

An OS transistor has extremely low current that flows between a source and a drain in an off state, that is, leakage current. The NOSRAM can be used as a nonvolatile memory by retaining electric charges corresponding to data in the memory cell, using characteristics of an extremely low leakage current. In particular, the NOSRAM is capable of reading out retained data without destruction (non-destructive reading), and thus is suitable for arithmetic processing in which only a data reading operation is repeated many times.

Here, a structure example of the main memory 33 using the NOSRAM as a memory cell is described.

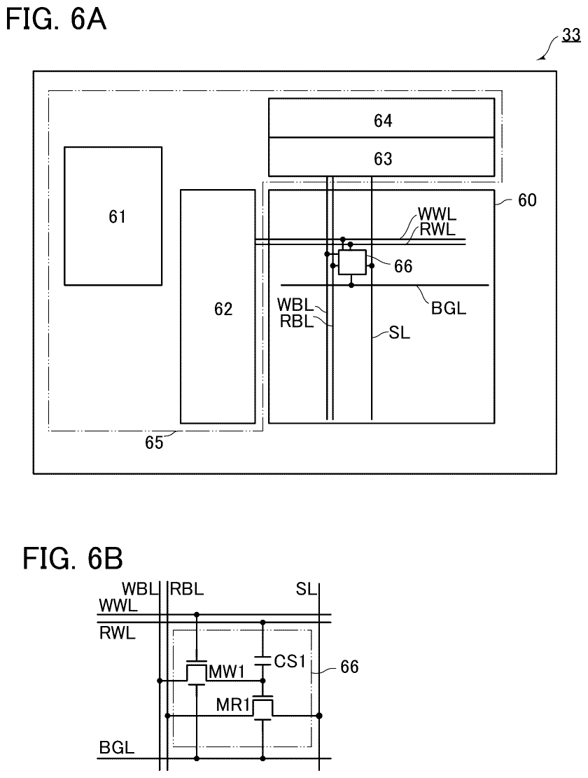

The main memory 33 illustrated in FIG. 6A includes a memory cell array 60 and a peripheral circuit 65. A control circuit 61, a row circuit 62, a column circuit 63, and an input/output circuit 64 are provided to form the peripheral circuit 65.

The memory cell array 60 includes a memory cell 66, a word line RWL, a word line WWL, a bit line RBL, a bit line WBL, a source line SL, and a wiring BGL. Note that the word line RWL is referred to as a read word line in some cases. Note that the word line WWL is referred to as a write word line in some cases. The bit line RBL may be referred to as a read bit line. The bit line WBL may be referred to as a write bit line.

The control circuit 61 controls the main memory 33 as a whole and performs data writing and data reading. The control circuit 61 processes command signals from the outside (e.g., a chip enable signal, a write enable signal, and the like) and generates control signals for other circuits of the peripheral circuit 65.

The row circuit 62 has a function of selecting a row to be accessed. For example, the row circuit 62 includes a row decoder and a word line driver. The column circuit 63 has a function of precharging the bit lines WBL and RBL, a function of writing data to the bit line WBL, a function of amplifying data of the bit line RBL, a function of reading out data from the bit line RBL, and the like. The input/output circuit 64 has a function of holding data for writing, a function of holding readout data, and the like.

The structure of the peripheral circuit 65 is changed as appropriate depending on the structure, readout method, writing method, or the like of the memory cell array 60. Part of the peripheral circuit 65 is preferably provided in the base die 20.

FIG. 6B illustrates a circuit structure example of the memory cell 66. The memory cell 66 here is a 2-transistor (2T) gain cell. The memory cell 66 includes transistors MW1 and MR1 and a capacitor CS1. The transistor MW1 is a write transistor and the transistor MR1 is a readout transistor. Backgates of the transistors MW1 and MR1 are electrically connected to the wiring BGL.

Since the readout transistor is composed of an OS transistor, the memory cell 66 does not consume power for data retention. Thus, the memory cell 66 is a memory cell with low power consumption that can retain data for a long time, and the memory device 33 can be used as a nonvolatile memory device.

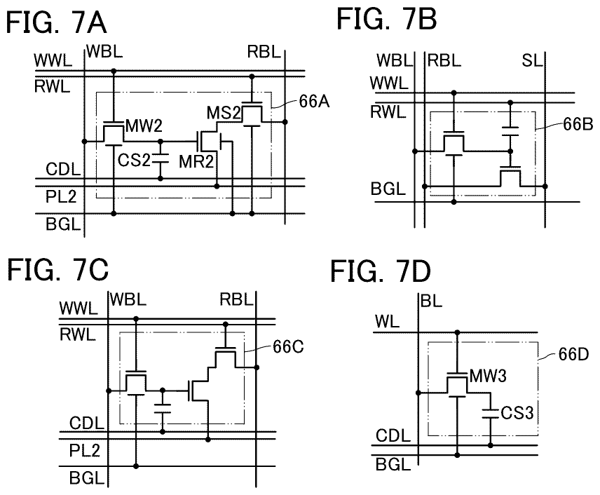

Other structure examples of a memory cell are described with reference to FIG. 7A to FIG. 7D.

A memory cell 66A illustrated in FIG. 7A is a 3T gain cell, which includes transistors MW2, MR2, and MS2, and a capacitor CS2. The transistors MW2, MR2, and MS2 are a write transistor, a readout transistor, and a selection transistor, respectively. Backgates of the transistors MW2, MR2, and MS2 are electrically connected to the wiring BGL. The memory cell 66A is electrically connected to the word lines RWL and WWL, the bit lines RBL and WBL, a capacitor line CDL, and a power supply line PL2. For example, a voltage GND (low-level-side power supply voltage) is input to the capacitor line CDL and the power supply line PL2.

FIG. 7B illustrates another structure example of a 2T gain cell. In a memory cell 66B illustrated in FIG. 7B, a readout transistor is an OS transistor not having a back gate.

FIG. 7C illustrates another structure example of a 3T gain cell. In a memory cell 66C illustrated in FIG. 7C, a readout transistor and a selection transistor are each an OS transistor not having a back gate.

In the above-described gain cells, a bit line serving as both the bit line RBL and the bit line WBL may be provided.

Although the NOSRAM is described as an example of a structure applicable to the memory cell 66, another structure may be employed as long as the memory cell can be formed using an OS transistor. For example, a DOSRAM that is a memory circuit including OS transistors may be used as well. A DOSRAM (registered trademark) is an abbreviation for “Dynamic Oxide Semiconductor RAM,” which indicates a RAM including a 1T (transistor) 1C (capacitor)-type memory cell. The DOSRAM is a DRAM formed using an OS transistor, and the DOSRAM is a memory that temporarily stores information sent from the outside. The DOSRAM is a memory utilizing low off-state current of an OS transistor.

FIG. 7D illustrates an example of a 1T1C (capacitor) memory cell. A memory cell 66D illustrated in FIG. 7D is electrically connected to a word line WL, the bit line BL, the capacitor line CDL, and the wiring BGL. The memory cell 66D includes a transistor MW3 and a capacitor CS3. A backgate of the transistor MW3 is electrically connected to the wiring BGL.

In the case where the memory cell 66 is a NOSRAM or a DOSRAM, the other portions are preferably power gated with a voltage that turns off the transistor (the transistor MW1 in FIG. 6B) that is an access transistor applied to the word line WWL connected to the gate of the transistor. With this structure, the supply of power supply voltages can be stopped while data is stored in the memory cell 66.

This embodiment can be implemented in combination with the other embodiments described in this specification as appropriate.

### Embodiment 3

In this embodiment, structures of transistors that can be used in the semiconductor device described in the above embodiments will be described. For example, a structure in which transistors having different electrical characteristics are provided to be stacked will be described. With the structure, the flexibility in design of the semiconductor device can be increased. When transistors having different electrical characteristics are provided to be stacked, the integration degree of the semiconductor device can be increased.

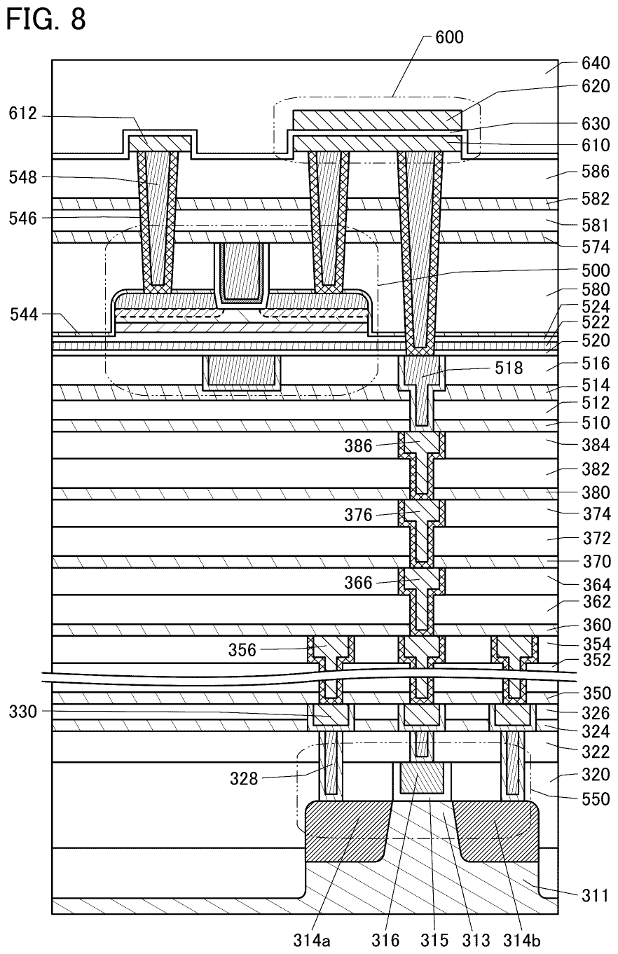

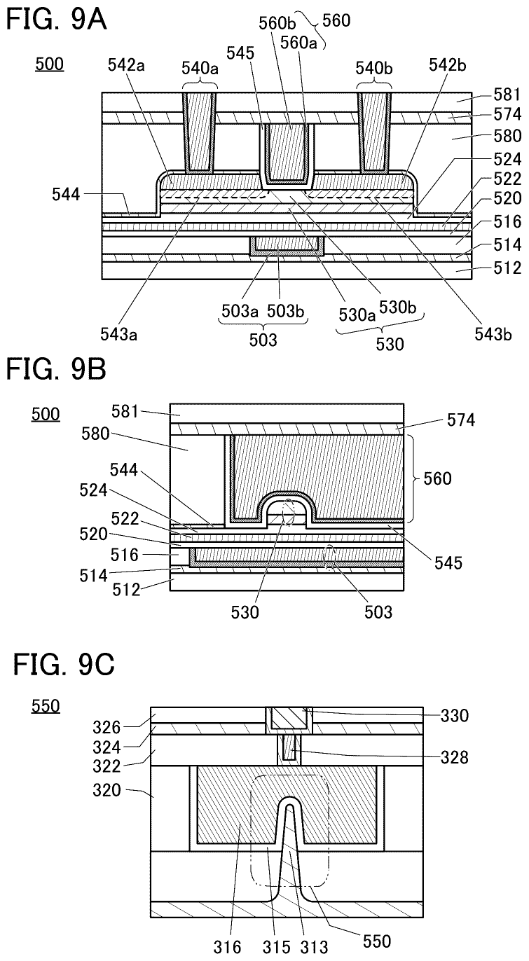

FIG. 8 illustrates part of a cross-sectional structure of a semiconductor device. The semiconductor device illustrated in FIG. 8 includes a transistor 550, a transistor 500, and a capacitor 600. FIG. 9A is a cross-sectional view of the transistor 500 in the channel length direction, FIG. 9B is a cross-sectional view of the transistor 500 in the channel width direction, and FIG. 9C is a cross-sectional view of the transistor 550 in the channel width direction. For example, the transistor 500 corresponds to the Si transistor described in the above embodiment and the transistor 550 corresponds to the OS transistor.

In FIG. 8, the transistor 500 is provided above the transistor 550, and the capacitor 600 is provided above the transistor 550 and the transistor 500.

The transistor 550 is provided in and on a substrate 311 and includes a conductor 316, an insulator 315, a semiconductor region 313 that is part of the substrate 311, and a low-resistance region 314a and a low-resistance region 314b functioning as a source region and a drain region.

As illustrated in FIG. 9C, the top surface and the side surface in the channel width direction of the semiconductor region 313 of the transistor 550 are covered with the conductor 316 with the insulator 315 positioned therebetween. Such a Fin-type transistor 550 can have an increased effective channel width and thus have improved on-state characteristics. In addition, contribution of the electric field of the gate electrode can be increased, so that the off-state characteristics of the transistor 550 can be improved.

Note that the transistor 550 may be either a p-channel transistor or an n-channel transistor.

It is preferable that a region of the semiconductor region 313 where a channel is formed, a region in the vicinity thereof, the low-resistance regions 314a and 314b functioning as the source and drain regions, and the like include a semiconductor such as a silicon-based semiconductor, further preferably single crystal silicon. Alternatively, a material including Ge (germanium), SiGe (silicon germanium), GaAs (gallium arsenide), GaAlAs (gallium aluminum arsenide), or the like may be included. Silicon whose effective mass is adjusted by applying stress to the crystal lattice and thereby changing the lattice spacing may be included. Alternatively, the transistor 550 may be a high electron mobility transistor (HEMT) with GaAs and GaAlAs, or the like.

The low-resistance regions 314a and 314b include an element that imparts n-type conductivity, such as arsenic or phosphorus, or an element that imparts p-type conductivity, such as boron, in addition to a semiconductor material used for the semiconductor region 313.

The conductor 316 functioning as a gate electrode can be formed using a semiconductor material such as silicon including the element that imparts n-type conductivity, such as arsenic or phosphorus, or the element that imparts p-type conductivity, such as boron, or a conductive material such as a metal material, an alloy material, or a metal oxide material.

Note that a material used for a conductor determines the work function; thus, selecting the material of the conductor can adjust the threshold voltage of a transistor. Specifically, titanium nitride, tantalum nitride, or the like is preferably used for the conductor. Furthermore, in order to ensure the conductivity and embeddability, a stacked layer of metal materials such as tungsten and aluminum is preferably used for the conductor. In particular, tungsten is preferably used in terms of heat resistance.

The transistor 550 may be formed using an soi (silicon on insulator) substrate or the like.

As the SOI substrate, any of the following substrates may be used: a SIMOX (Separation by Implanted Oxygen) substrate formed in such a manner that an oxygen ion is implanted into a mirror-polished wafer, and then, an oxide layer is formed at a certain depth from the surface and defects generated in a surface layer are eliminated by high-temperature annealing, and an SOI substrate formed by a Smart-Cut method in which a semiconductor substrate is cleaved by utilizing growth of a minute void, which is formed by implantation of a hydrogen ion, by heat treatment; an ELTRAN method (registered trademark: Epitaxial Layer Transfer); or the like. A transistor formed using a single crystal substrate includes a single crystal semiconductor in a channel formation region.

An insulator 320, an insulator 322, an insulator 324, and an insulator 326 are provided to be stacked sequentially to cover the transistor 550.

The insulator 320, the insulator 322, the insulator 324, and the insulator 326 are formed using, for example, silicon oxide, silicon oxynitride, silicon nitride oxide, silicon nitride, aluminum oxide, aluminum oxynitride, aluminum nitride oxide, or aluminum nitride.

Note that in this specification, silicon oxynitride refers to a material that has a higher oxygen content than a nitrogen content, and silicon nitride oxide refers to a material that has a higher nitrogen content than an oxygen content. Moreover, in this specification, aluminum oxynitride refers to a material that has a higher oxygen content than a nitrogen content, and aluminum nitride oxide refers to a material that has a higher nitrogen content than an oxygen content.

The insulator 322 may function as a planarization film for eliminating a level difference caused by the transistor 550 or the like underlying the insulator 322. For example, the top surface of the insulator 322 may be planarized by planarization treatment using a chemical mechanical polishing (CMP) method or the like to increase the level of planarity.

The insulator 324 is preferably formed using a film having a barrier property that prevents hydrogen, impurities, or the like from diffusing from the substrate 311, the transistor 550, or the like into a region where the transistor 500 is provided.

For the film having a barrier property against hydrogen, for example, silicon nitride deposited by a CVD method can be used. Here, diffusion of hydrogen into a semiconductor element including an oxide semiconductor, such as the transistor 500, degrades the characteristics of the semiconductor element in some cases. Thus, a film that inhibits hydrogen diffusion is preferably provided between the transistor 500 and the transistor 550. Specifically, the film that inhibits hydrogen diffusion is a film from which a small amount of hydrogen is released.

The amount of released hydrogen can be measured by thermal desorption spectroscopy (TDS), for example. The amount of hydrogen released from the insulator 324 that is converted into hydrogen atoms per unit area of the insulator 324 is less than or equal to 1×10¹⁶ atoms/cm², preferably less than or equal to 5×10¹⁵ atoms/cm² in TDS analysis in a film-surface temperature range of 50 ° C. to 500° C., for example.

Note that the dielectric constant of the insulator 326 is preferably lower than that of the insulator 324. For example, the dielectric constant of the insulator 326 is preferably lower than 4, further preferably lower than 3. For example, the dielectric constant of the insulator 326 is preferably less than or equal to 0.7 times that of the insulator 324, further preferably less than or equal to 0.6 times that of the insulator 324. In the case where a material with a low dielectric constant is used for an interlayer film, the parasitic capacitance between wirings can be reduced.

A conductor 328, a conductor 330, and the like that are connected to the capacitor 600 or the transistor 500 are embedded in the insulators 320, 322, 324, and 326. Note that the conductor 328 and the conductor 330 each function as a plug or a wiring. A plurality of conductors functioning as plugs or wirings are collectively denoted by the same reference numeral in some cases. In this specification and the like, a wiring and a plug connected to the wiring may be a single component. That is, part of a conductor functions as a wiring in some cases, and part of a conductor functions as a plug in other cases.

As a material for each of the plugs and wirings (e.g., the conductor 328 and the conductor 330), a conductive material such as a metal material, an alloy material, a metal nitride material, or a metal oxide material can be used in a single-layer structure or a stacked-layer structure. It is preferable to use a high-melting-point material that has both heat resistance and conductivity, such as tungsten or molybdenum, and it is particularly preferable to use tungsten. Alternatively, a low-resistance conductive material such as aluminum or copper is preferably used. The use of a low-resistance conductive material can reduce wiring resistance.

A wiring layer may be provided over the insulator 326 and the conductor 330. For example, an insulator 350, an insulator 352, and an insulator 354 are stacked sequentially in FIG. 8. Furthermore, a conductor 356 is formed in the insulator 350, the insulator 352, and the insulator 354. The conductor 356 has a function of a plug or a wiring that is connected to the transistor 550. Note that the conductor 356 can be formed using a material similar to that for the conductor 328 and the conductor 330.

Note that for example, the insulator 350 is preferably formed using an insulator having a barrier property against hydrogen, like the insulator 324. Furthermore, the conductor 356 preferably includes a conductor having a barrier property against hydrogen. The conductor having a barrier property against hydrogen is formed particularly in an opening portion of the insulator 350 having a barrier property against hydrogen. In such a structure, the transistor 550 and the transistor 500 can be separated by a barrier layer, so that the hydrogen diffusion from the transistor 550 into the transistor 500 can be inhibited.

Note that as the conductor having a barrier property against hydrogen, tantalum nitride is preferably used, for example. By stacking tantalum nitride and tungsten, which has high conductivity, hydrogen diffusion from the transistor 550 can be inhibited while the conductivity of a wiring is ensured. In that case, a tantalum nitride layer having a barrier property against hydrogen is preferably in contact with the insulator 350 having a barrier property against hydrogen.

A wiring layer may be provided over the insulator 354 and the conductor 356. For example, an insulator 360, an insulator 362, and an insulator 364 are stacked sequentially in FIG. 8. Furthermore, a conductor 366 is formed in the insulator 360, the insulator 362, and the insulator 364. The conductor 366 functions as a plug or a wiring. Note that the conductor 366 can be formed using a material similar to that for the conductor 328 and the conductor 330.

Note that for example, the insulator 360 is preferably formed using an insulator having a barrier property against hydrogen, like the insulator 324. Furthermore, the conductor 366 preferably includes a conductor having a barrier property against hydrogen. The conductor having a barrier property against hydrogen is formed particularly in an opening portion of the insulator 360 having a barrier property against hydrogen. In such a structure, the transistor 550 and the transistor 500 can be separated by a barrier layer, so that the hydrogen diffusion from the transistor 550 into the transistor 500 can be inhibited.

A wiring layer may be provided over the insulator 364 and the conductor 366. For example, an insulator 370, an insulator 372, and an insulator 374 are stacked sequentially in FIG. 8. Furthermore, a conductor 376 is formed in the insulator 370, the insulator 372, and the insulator 374. The conductor 376 functions as a plug or a wiring. Note that the conductor 376 can be formed using a material similar to that for the conductor 328 and the conductor 330.

Note that for example, the insulator 370 is preferably formed using an insulator having a barrier property against hydrogen, like the insulator 324. Furthermore, the conductor 376 preferably includes a conductor having a barrier property against hydrogen. The conductor having a barrier property against hydrogen is formed particularly in an opening portion of the insulator 370 having a barrier property against hydrogen. In such a structure, the transistor 550 and the transistor 500 can be separated by a barrier layer, so that the hydrogen diffusion from the transistor 550 into the transistor 500 can be inhibited.

A wiring layer may be provided over the insulator 374 and the conductor 376. For example, an insulator 380, an insulator 382, and an insulator 384 are stacked sequentially in FIG. 8. Furthermore, a conductor 386 is formed in the insulator 380, the insulator 382, and the insulator 384. The conductor 386 functions as a plug or a wiring. Note that the conductor 386 can be formed using a material similar to that for the conductor 328 and the conductor 330.

Note that for example, the insulator 380 is preferably formed using an insulator having a barrier property against hydrogen, like the insulator 324. Furthermore, the conductor 386 preferably includes a conductor having a barrier property against hydrogen. The conductor having a barrier property against hydrogen is formed particularly in an opening portion of the insulator 380 having a barrier property against hydrogen. In such a structure, the transistor 550 and the transistor 500 can be separated by a barrier layer, so that the hydrogen diffusion from the transistor 550 into the transistor 500 can be inhibited.

Although the wiring layer including the conductor 356, the wiring layer including the conductor 366, the wiring layer including the conductor 376, and the wiring layer including the conductor 386 are described above, the semiconductor device of this embodiment is not limited thereto. The number of wiring layers similar to the wiring layer including the conductor 356 may be three or less, or five or more.

An insulator 510, an insulator 512, an insulator 514, and an insulator 516 are stacked sequentially over the insulator 384. A material having a barrier property against oxygen, hydrogen, or the like is preferably used for any of the insulator 510, the insulator 512, the insulator 514, and the insulator 516.

For example, each of the insulator 510 and the insulator 514 is preferably formed using a film having a barrier property which prevents hydrogen, impurities, or the like from diffusing from the substrate 311, a region where the transistor 550 is provided, or the like into a region where the transistor 500 is provided. Thus, each of the insulator 510 and the insulator 514 can be formed using a material similar to that for the insulator 324.

For the film having a barrier property against hydrogen, for example, silicon nitride deposited by a CVD method can be used. Here, diffusion of hydrogen into a semiconductor element including an oxide semiconductor, such as the transistor 500, degrades the characteristics of the semiconductor element in some cases. Thus, a film that inhibits hydrogen diffusion is preferably provided between the transistor 500 and the transistor 550. Specifically, the film that inhibits hydrogen diffusion is a film from which a small amount of hydrogen is released.

For the film having a barrier property against hydrogen used for each of the insulator 510 and the insulator 514, for example, a metal oxide such as aluminum oxide, hafnium oxide, or tantalum oxide is preferably used.

In particular, aluminum oxide has an excellent blocking effect that prevents permeation of oxygen and impurities such as hydrogen and moisture that cause a change in electrical characteristics of the transistor. Accordingly, the use of aluminum oxide can prevent entry of impurities such as hydrogen and moisture into the transistor 500 during and after a manufacturing process of the transistor. In addition, release of oxygen from the oxide included in the transistor 500 can be prevented. Thus, aluminum oxide is suitably used for a protective film of the transistor 500.

The insulator 512 and the insulator 516 can be formed using a material similar to that for the insulator 320, for example. In the case where a material with a relatively low dielectric constant is used for these insulators, the parasitic capacitance between wirings can be reduced. A silicon oxide film, a silicon oxynitride film, or the like can be used for the insulator 512 and the insulator 516, for example.

A conductor 518, a conductor included in the transistor 500 (e.g., a conductor 503), and the like are embedded in the insulator 510, the insulator 512, the insulator 514, and the insulator 516. Note that the conductor 518 functions as a plug or a wiring that is connected to the capacitor 600 or the transistor 550. The conductor 518 can be formed using a material similar to that for the conductor 328 and the conductor 330.

In particular, the conductor 518 in a region in contact with the insulator 510 and the insulator 514 is preferably a conductor having a barrier property against oxygen, hydrogen, and water. In such a structure, the transistor 550 and the transistor 500 can be separated by a layer having a barrier property against oxygen, hydrogen, and water, so that the hydrogen diffusion from the transistor 550 into the transistor 500 can be inhibited.

### The Transistor 500 Is Provided Over the Insulator 516.

As illustrated in FIG. 9A and FIG. 9B, the transistor 500 includes the conductor 503 placed so as to be embedded in the insulator 514 and the insulator 516, an insulator 520 placed over the insulator 516 and the conductor 503, an insulator 522 placed over the insulator 520, an insulator 524 placed over the insulator 522, an oxide 530a placed over the insulator 524, an oxide 530b placed over the oxide 530a, a conductor 542a and a conductor 542b placed apart from each other over the oxide 530b, an insulator 580 that is placed over the conductor 542a and the conductor 542b and has an opening overlapping with an area between the conductor 542a and the conductor 542b, an insulator 545 placed on a bottom surface and a side surface of the opening, and a conductor 560 that is placed on a formation surface of the insulator 545.

As illustrated in FIG. 9A and FIG. 9B, an insulator 544 is preferably placed between the insulator 580 and the oxide 530a, the oxide 530b, the conductor 542a, and the conductor 542b. In addition, as illustrated in FIG. 9A and FIG. 9B, the conductor 560 preferably includes a conductor 560a provided inside the insulator 545 and a conductor 560b provided to be embedded inside the conductor 560a. Moreover, as illustrated in FIG. 9A and FIG. 9B, an insulator 574 is preferably placed over the insulator 580, the conductor 560, and the insulator 545.

In this specification and the like, the oxide 530a and the oxide 530b may be collectively referred to as an oxide 530.

The transistor 500 has, in the region where the channel is formed and its vicinity, a structure in which the oxide 530a and the oxide 530b are stacked; however, the present invention is not limited thereto. For example, a single layer of the oxide 530b or a stacked-layer structure of three or more layers may be provided.

Although the conductor 560 has a two-layer structure in the transistor 500, the present invention is not limited thereto. For example, the conductor 560 may have a single-layer structure or a stacked-layer structure of three or more layers. The transistor 500 illustrated in FIG. 8 and FIG. 9A is just an example and is not limited to the structure illustrated therein, and an appropriate transistor can be used in accordance with a circuit structure, a driving method, or the like.

Here, the conductor 560 functions as a gate electrode of the transistor, and the conductor 542a and the conductor 542b function as a source electrode and a drain electrode. As described above, the conductor 560 is embedded in the opening of the insulator 580 and the region sandwiched between the conductor 542a and the conductor 542b. The positions of the conductor 560, the conductor 542a, and the conductor 542b with respect to the opening of the insulator 580 are selected in a self-aligned manner. That is, in the transistor 500, the gate electrode can be positioned between the source electrode and the drain electrode in a self-aligned manner. Thus, the conductor 560 can be formed without an alignment margin, resulting in a reduction in the area occupied by the transistor 500. Accordingly, miniaturization and high integration of the semiconductor device can be achieved.

In addition, since the conductor 560 is formed in the region between the conductor 542a and the conductor 542b in a self-aligned manner, the conductor 560 has neither a region overlapping with the conductor 542a nor a region overlapping with the conductor 542b. Thus, parasitic capacitance between the conductor 560 and the conductors 542a and 542b can be reduced. As a result, the transistor 500 can have increased switching speed and excellent frequency characteristics.

The conductor 560 functions as a first gate (also referred to as a top gate) electrode in some cases. The conductor 503 functions as a second gate (also referred to as a bottom gate) electrode in some cases. In that case, by changing a potential applied to the conductor 503 independently of a potential applied to the conductor 560, the threshold voltage of the transistor 500 can be controlled. In particular, when a negative potential is applied to the conductor 503, the threshold voltage of the transistor 500 can be increased to higher than 0 V, and the off-state current can be reduced. Thus, a drain current when a potential applied to the conductor 560 is 0 V can be smaller in the case where a negative potential is applied to the conductor 503 than in the case where the negative potential is not applied to the conductor 503.

The conductor 503 is placed to overlap with the oxide 530 and the conductor 560. Accordingly, in the case where potentials are applied to the conductor 560 and the conductor 503, an electric field generated from the conductor 560 and an electric field generated from the conductor 503 are connected, thereby covering the channel formation region in the oxide 530.

In this specification and the like, a transistor structure in which a channel formation region is electrically surrounded by the electric field of a first gate electrode is referred to as a surrounded channel (S-channel) structure. The S-channel structure disclosed in this specification and the like is different from a Fin structure or a planar structure. The S-channel structure disclosed in this specification and the like can be regarded as a kind of the Fin structure. In this specification and the like, the Fin structure refers to a structure in which at least two surfaces (specifically, two surfaces, three surfaces, four surfaces, or the like) of a channel are covered with a gate electrode. With the use of the Fin structure or the S-channel structure, a transistor with high resistance to a short-channel effect, i.e., a transistor in which a short-channel effect is unlikely to occur, can be obtained.

When the transistor has the above-described S-channel structure, the channel formation region can be electrically surrounded. Since the S-channel structure is a structure with the electrically surrounded channel formation region, the S-channel structure is, in a sense, equivalent to a GAA (Gate All Around) structure or a LGAA (Lateral Gate All Around) structure. In the transistor having any of the S-channel structure, GAA structure, and LGAA structure, the channel formation region that is formed at the interface between the oxide 530 and the gate insulator or in the vicinity of the interface can spread throughout the entire bulk of the oxide 530. Consequently, the density of current flowing through the transistor can be improved, so that the on-state current or the field-effect mobility of the transistor can be expected to increase.

The conductor 503 has a structure similar to that of the conductor 518; a conductor 503a is formed in contact with an inner wall of the opening in the insulator 514 and the insulator 516, and a conductor 503b is formed on the inner side. Although the transistor 500 having a structure in which the conductor 503a and the conductor 503b are stacked is described, the present invention is not limited thereto. For example, the conductor 503 may have a single-layer structure or a stacked-layer structure of three or more layers.

The conductor 503a is preferably formed using a conductive material having a function of inhibiting diffusion of impurities such as a hydrogen atom, a hydrogen molecule, a water molecule, and a copper atom (a conductive material through which the above impurities are less likely to pass). Alternatively, the conductor 503a is preferably formed using a conductive material having a function of inhibiting diffusion of oxygen (e.g., at least one of oxygen atoms, oxygen molecules, and the like) (a conductive material through which the above oxygen is less likely to pass). Note that in this specification, a function of inhibiting diffusion of impurities or oxygen means a function of inhibiting diffusion of any one or all of the above impurities and the above oxygen.

For example, when the conductor 503a has a function of inhibiting diffusion of oxygen, the conductivity of the conductor 503b can be prevented from being lowered because of oxidation.

In the case where the conductor 503 also functions as a wiring, the conductor 503b is preferably formed using a conductive material with high conductivity that includes tungsten, copper, or aluminum as its main component. Although the conductor 503 has a stacked layer of the conductor 503a and the conductor 503b in this embodiment, the conductor 503 may have a single-layer structure.

The insulator 520, the insulator 522, and the insulator 524 function as a second gate insulating film.

Here, an insulator including oxygen more than that in the stoichiometric composition is preferably used as the insulator 524 in contact with the oxide 530. Such oxygen is easily released from the film by heating. In this specification and the like, oxygen released by heating is sometimes referred to as excess oxygen. That is, a region including excess oxygen (also referred to as an “excess-oxygen region”) is preferably formed in the insulator 524. When such an insulator including excess oxygen is provided in contact with the oxide 530, oxygen vacancies (also referred to as Vo) in the oxide 530 can be reduced, leading to an improvement in reliability of the transistor 500. When hydrogen enters the oxygen vacancies in the oxide 530, such defects (hereinafter, referred to as VoH in some cases) serve as donors and generate electrons serving as carriers in some cases. In other cases, bonding of part of hydrogen to oxygen bonded to a metal atom generates electrons serving as carriers. Thus, a transistor including an oxide semiconductor that includes a large amount of hydrogen is likely to have normally-on characteristics. Moreover, hydrogen in an oxide semiconductor is easily transferred by a stress such as heat or an electric field; thus, a large amount of hydrogen in an oxide semiconductor might reduce the reliability of a transistor. In one embodiment of the present invention, VoH in the oxide 530 is preferably reduced as much as possible so that the oxide 530 becomes a highly purified intrinsic or substantially highly purified intrinsic oxide. In order to obtain such an oxide semiconductor with sufficiently reduced VoH, it is important to remove impurities such as moisture and hydrogen in the oxide semiconductor (this treatment is also referred to as “dehydration” or “dehydrogenation treatment”) and supply oxygen to the oxide semiconductor to fill oxygen vacancies (this treatment is also referred to as “oxygen adding treatment”). When an oxide semiconductor with sufficiently reduced impurities such as VoH is used for a channel formation region of a transistor, the transistor can have stable electrical characteristics.

As the insulator including the excess-oxygen region, specifically, an oxide material that releases part of oxygen by heating is preferably used. An oxide that releases oxygen by heating is an oxide film in which the amount of released oxygen converted into oxygen atoms is greater than or equal to 1.0×10¹⁸atoms/cm³, preferably greater than or equal to 1.0×10¹⁹atoms/cm³, further preferably greater than or equal to 2.0×10¹⁹ atoms/cm³ or greater than or equal to 3.0×10²⁰ atoms/cm³ in TDS (Thermal Desorption Spectroscopy) analysis. In the TDS analysis, the film-surface temperature is preferably higher than or equal to 100° C. and lower than or equal to 700° C., or higher than or equal to 100° C. and lower than or equal to 400° C.

One or more of heat treatment, microwave treatment, and RF treatment may be performed in a state in which the insulator including the excess-oxygen region and the oxide 530 are in contact with each other. By the treatment, water or hydrogen in the oxide 530 can be removed. For example, in the oxide 530, dehydrogenation can be performed when a reaction in which a bond of VoH is cut occurs, i.e., a reaction of “VoH→Vo+H” occurs. Part of hydrogen generated at this time is bonded to oxygen to be H₂O, and removed from the oxide 530 or an insulator near the oxide 530 in some cases. In other cases, part of hydrogen is gettered by the conductor 542.

For the microwave treatment, for example, an apparatus including a power supply that generates high-density plasma or an apparatus including a power supply that applies RF to the substrate side is suitably used. For example, the use of high-density plasma and a gas including oxygen enables high-density oxygen radicals to be generated, and application of the RF to the substrate side allows the oxygen radicals generated by the high-density plasma to be efficiently introduced into the oxide 530 or an insulator in the vicinity of the oxide 530. The microwave treatment is performed under a pressure of 133 Pa or higher, preferably 200 Pa or higher, further preferably 400 Pa or higher. As a gas introduced into an apparatus for performing the microwave treatment, for example, oxygen and argon are used and the oxygen flow rate ratio (O₂/(O₂+Ar)) is lower than or equal to 50%, preferably higher than or equal to 10% and lower than or equal to 30%.

In a manufacturing process of the transistor 500, the heat treatment is preferably performed with the surface of the oxide 530 exposed. For example, the heat treatment is performed at a temperature higher than or equal to 100° C. and lower than or equal to 450° C., preferably higher than or equal to 350° C. and lower than or equal to 400° C. The heat treatment is performed in a nitrogen gas atmosphere, an inert gas atmosphere, or an atmosphere including an oxidizing gas at 10 ppm or more, 1% or more, or 10% or more. For example, the heat treatment is preferably performed in an oxygen atmosphere. Accordingly, oxygen can be supplied to the oxide 530 to reduce oxygen vacancies (Vo). The heat treatment may be performed under a reduced pressure. Alternatively, the heat treatment may be performed in such a manner that heat treatment is performed in a nitrogen gas atmosphere or an inert gas atmosphere, and then another heat treatment is performed in an atmosphere including an oxidizing gas at 10 ppm or more, 1% or more, or 10% or more in order to compensate for released oxygen. Alternatively, the heat treatment may be performed in such a manner that heat treatment is performed in an atmosphere including an oxidizing gas at 10 ppm or more, 1% or more, or 10% or more, and then another heat treatment is successively performed in a nitrogen gas atmosphere or an inert gas atmosphere.

Note that the oxygen adding treatment performed on the oxide 530 can promote a reaction in which oxygen vacancies in the oxide 530 are filled with supplied oxygen, i.e., a reaction of “Vo+O→null”. Furthermore, hydrogen remaining in the oxide 530 reacts with supplied oxygen, so that the hydrogen can be removed as H₂O (dehydration). This can inhibit recombination of hydrogen remaining in the oxide 530 with oxygen vacancies and formation of VoH.

In the case where the insulator 524 includes an excess-oxygen region, the insulator 522 preferably has a function of inhibiting diffusion of oxygen (e.g., oxygen atoms and oxygen molecules) (it is preferable that oxygen be less likely to pass through the insulator 522).

The insulator 522 preferably has a function of inhibiting diffusion of oxygen, impurities, or the like, in which case diffusion of oxygen included in the oxide 530 to the insulator 520 side is prevented. In addition, the conductor 503 can be inhibited from reacting with oxygen in the insulator 524, the oxide 530, or the like.

The insulator 522 preferably has a single-layer structure or a stacked-layer structure using an insulator including what is called a high-k material such as aluminum oxide, hafnium oxide, an oxide including aluminum and hafnium (hafnium aluminate), tantalum oxide, zirconium oxide, lead zirconate titanate (PZT), strontium titanate (SrTiO₃), or (Ba,Sr)TiO₃ (BST), for example. With miniaturization and high integration of a transistor, a problem such as generation of a leakage current sometimes arises because of a thin gate insulating film. When a high-k material is used for an insulator functioning as the gate insulating film, a gate potential at the time of operating the transistor can be reduced while the physical thickness of the gate insulating film is kept.

It is particularly preferable to use an insulator including an oxide of one or both of aluminum and hafnium, which is an insulating material having a function of inhibiting diffusion of impurities, oxygen, and the like (an insulating material through which the above oxygen is less likely to pass). Aluminum oxide, hafnium oxide, an oxide including aluminum and hafnium (hafnium aluminate), or the like is preferably used for the insulator including an oxide of one or both of aluminum and hafnium. The insulator 522 formed of such a material functions as a layer that inhibits release of oxygen from the oxide 530 or entry of impurities such as hydrogen from the periphery of the transistor 500 into the oxide 530.

Alternatively, aluminum oxide, bismuth oxide, germanium oxide, niobium oxide, silicon oxide, titanium oxide, tungsten oxide, yttrium oxide, or zirconium oxide may be added to the insulator, for example. Alternatively, the insulator may be subjected to nitriding treatment. Silicon oxide, silicon oxynitride, or silicon nitride may be stacked over the insulator.

It is preferable that the insulator 520 be thermally stable. For example, silicon oxide and silicon oxynitride are preferred because of their thermal stability. Furthermore, combination of an insulator which is a high-k material and silicon oxide or silicon oxynitride enables the insulator 520 to have a stacked-layer structure that is thermally stable and has a high dielectric constant.

Note that the transistor 500 in FIG. 9A and FIG. 9B includes the insulator 520, the insulator 522, and the insulator 524 as the second gate insulating film having a three-layer structure; however, the second gate insulating film may have a single-layer structure, a two-layer structure, or a stacked-layer structure of four or more layers. In that case, the stacked layers are not necessarily formed of the same material and may be formed of different materials.

In the transistor 500, a metal oxide functioning as an oxide semiconductor is used as the oxide 530 including a channel formation region. For example, as the oxide 530, a metal oxide such as an In-M-Zn oxide (M is one or more of aluminum, gallium, yttrium, copper, vanadium, beryllium, boron, titanium, iron, nickel, germanium, zirconium, molybdenum, lanthanum, cerium, neodymium, hafnium, tantalum, tungsten, magnesium, and the like) is preferably used.

The metal oxide functioning as an oxide semiconductor may be formed by a sputtering method or an atomic layer deposition (ALD) method. Note that the metal oxide functioning as an oxide semiconductor will be described in detail in another embodiment.

The metal oxide functioning as the channel formation region in the oxide 530 has a band gap of 2 eV or more, preferably 2.5 eV or more. The use of a metal oxide having such a wide band gap can reduce the off-state current of a transistor.

When the oxide 530a is provided below the oxide 530b in the oxide 530, impurities can be inhibited from diffusing into the oxide 530b from the components formed below the oxide 530a.

The oxide 530 preferably has a structure including a plurality of oxide layers that differ in the atomic ratio of metal atoms. Specifically, the atomic ratio of the element M to constituent elements in the metal oxide used as the oxide 530a is preferably greater than that in the metal oxide used as the oxide 530b. Moreover, the atomic ratio of the element M to In in the metal oxide used as the oxide 530a is preferably greater than that in the metal oxide used as the oxide 530b. Moreover, the atomic ratio of In to the element M in the metal oxide used as the oxide 530b is preferably greater than that in the metal oxide used as the oxide 530a.

The energy of the conduction band minimum of the oxide 530a is preferably higher than that of the oxide 530b. In other words, the electron affinity of the oxide 530a is preferably smaller than that of the oxide 530b.

Here, the energy level of the conduction band minimum is gradually varied at a junction portion of the oxide 530a and the oxide 530b. In other words, the energy level of the conduction band minimum at a junction portion of the oxide 530a and the oxide 530b is continuously varied or continuously connected. To vary the energy level gradually, the density of defect states in a mixed layer formed at the interface between the oxide 530a and the oxide 530b is preferably made low.

Specifically, when the oxide 530a and the oxide 530b include the same element (as a main component) in addition to oxygen, a mixed layer with a low density of defect states can be formed. For example, in the case where the oxide 530b is an In—Ga—Zn oxide, it is preferable to use an In—Ga—Zn oxide, a Ga—Zn oxide, gallium oxide, or the like as the oxide 530a.

At this time, the oxide 530b serves as a main carrier path. When the oxide 530a has the above structure, the density of defect states at the interface between the oxide 530a and the oxide 530b can be made low. Thus, the influence of interface scattering on carrier conduction is small, and the transistor 500 can have a high on-state current.

The conductor 542a and the conductor 542b functioning as the source electrode and the drain electrode are provided over the oxide 530b. For the conductor 542a and the conductor 542b, it is preferable to use a metal element selected from aluminum, chromium, copper, silver, gold, platinum, tantalum, nickel, titanium, molybdenum, tungsten, hafnium, vanadium, niobium, manganese, magnesium, zirconium, beryllium, indium, ruthenium, iridium, strontium, and lanthanum; an alloy including any of the above metal elements as its component; an alloy including a combination of the above metal elements; or the like. For example, tantalum nitride, titanium nitride, tungsten, a nitride including titanium and aluminum, a nitride including tantalum and aluminum, ruthenium oxide, ruthenium nitride, an oxide including strontium and ruthenium, an oxide including lanthanum and nickel, or the like is preferably used. Tantalum nitride, titanium nitride, a nitride including titanium and aluminum, a nitride including tantalum and aluminum, ruthenium oxide, ruthenium nitride, an oxide including strontium and ruthenium, and an oxide including lanthanum and nickel are preferable because they are oxidation-resistant conductive materials or materials that retain their conductivity even after absorbing oxygen. Furthermore, a metal nitride film such as a tantalum nitride film is preferable because it has a barrier property against hydrogen or oxygen.

Although the conductor 542a and the conductor 542b have a single-layer structure in FIG. 9A, they may have a stacked-layer structure of two or more layers. For example, a tantalum nitride film and a tungsten film may be stacked. Alternatively, a titanium film and an aluminum film may be stacked. Other examples include a two-layer structure in which an aluminum film is stacked over a tungsten film, a two-layer structure in which a copper film is stacked over a copper-magnesium-aluminum alloy film, a two-layer structure in which a copper film is stacked over a titanium film, and a two-layer structure in which a copper film is stacked over a tungsten film.

Other examples include a three-layer structure in which a titanium film or a titanium nitride film and an aluminum film or a copper film are stacked so that the aluminum film or the copper film overlaps with the titanium film or the titanium nitride film and a titanium film or a titanium nitride film is further stacked thereover and a three-layer structure in which a molybdenum film or a molybdenum nitride film and an aluminum film or a copper film are stacked so that the aluminum film or the copper film overlaps with the molybdenum film or the molybdenum nitride film and a molybdenum film or a molybdenum nitride film is further stacked thereover. Note that a transparent conductive material including indium oxide, tin oxide, or zinc oxide may be used.

As illustrated in FIG. 9A, a region 543a and a region 543b are sometimes formed as low-resistance regions at and near the interface between the oxide 530 and the conductor 542a (the conductor 542b). In that case, the region 543a functions as one of a source region and a drain region, and the region 543b functions as the other of the source region and the drain region. A channel formation region is formed in a region sandwiched between the region 543a and the region 543b.

When the conductor 542a (the conductor 542b) is provided in contact with the oxide 530, the oxygen concentration in the region 543a (the region 543b) sometimes decrease. In addition, a metal compound layer that includes the metal included in the conductor 542a (the conductor 542b) and the component of the oxide 530 is sometimes formed in the region 543a (the region 543b). In such cases, the carrier concentration of the region 543a (the region 543b) increases, and the region 543a (the region 543b) becomes a low-resistance region.

The insulator 544 is provided to cover the conductor 542a and the conductor 542b and inhibits oxidation of the conductor 542a and the conductor 542b. Here, the insulator 544 may be provided to cover the side surface of the oxide 530 and to be in contact with the insulator 524.

A metal oxide including one or two or more of hafnium, aluminum, gallium, yttrium, zirconium, tungsten, titanium, tantalum, nickel, germanium, neodymium, lanthanum, magnesium, and the like can be used as the insulator 544. For the insulator 544, silicon nitride oxide or silicon It is particularly preferable to use, as the insulator 544, aluminum oxide, hafnium oxide, an oxide including aluminum and hafnium (hafnium aluminate), or the like that is an insulator including an oxide of one or both of aluminum and hafnium. In particular, hafnium aluminate has higher heat resistance than a hafnium oxide film and thus is less likely to be crystallized by heat treatment in a later step. Note that the insulator 544 is not necessarily provided when the conductor 542a and the conductor 542b are oxidation-resistant materials or materials that do not significantly lose the conductivity even after absorbing oxygen. Design is determined as appropriate in consideration of required transistor characteristics.

The insulator 544 can inhibit impurities such as water and hydrogen included in the insulator 580 from diffusing into the oxide 530b. Moreover, the oxidation of the conductor 542 due to excess oxygen included in the insulator 580 can be inhibited.

The insulator 545 functions as a first gate insulating film. The insulator 545 is preferably formed using an insulator which includes excess oxygen and from which oxygen is released by heating, like the insulator 524.

Specifically, any of silicon oxide, silicon oxynitride, silicon nitride oxide, silicon nitride, silicon oxide to which fluorine is added, silicon oxide to which carbon is added, silicon oxide to which carbon and nitrogen are added, and porous silicon oxide each including excess oxygen can be used. In particular, silicon oxide and silicon oxynitride, which have thermal stability, are preferable.

When an insulator including excess oxygen is provided as the insulator 545, oxygen can be effectively supplied from the insulator 545 to the channel formation region of the oxide 530b. As in the insulator 524, the concentration of impurities such as water and hydrogen in the insulator 545 is preferably lowered. The thickness of the insulator 545 is preferably greater than or equal to 1 nm and less than or equal to 20 nm.

Furthermore, in order that excess oxygen included in the insulator 545 can be efficiently supplied to the oxide 530, a metal oxide may be provided between the insulator 545 and the conductor 560. The metal oxide preferably inhibits diffusion of oxygen from the insulator 545 into the conductor 560. Providing the metal oxide that inhibits diffusion of oxygen inhibits diffusion of excess oxygen from the insulator 545 into the conductor 560. That is, a reduction in the amount of excess oxygen supplied to the oxide 530 can be suppressed. Moreover, oxidization of the conductor 560 due to excess oxygen can be suppressed. The metal oxide is formed using a material that can be used for the insulator 544.

Note that the insulator 545 may have a stacked-layer structure like the second gate insulating film. With miniaturization and high integration of a transistor, a problem such as generation of a leakage current sometimes arises because of a thin gate insulating film. Thus, when an insulator functioning as a gate insulating film has a stacked-layer structure of a high-k material and a thermally stable material, a gate potential at the time of operating the transistor can be reduced while the physical thickness of the gate insulating film is kept. Furthermore, the stacked-layer structure can be thermally stable and have a high dielectric constant.

Although the conductor 560 functioning as the first gate electrode has a two-layer structure in FIG. 9A and FIG. 9B, the conductor 560 may have a single-layer structure or a stacked-layer structure of three or more layers.

The conductor 560a is preferably formed using a conductive material having a function of inhibiting diffusion of impurities such as a hydrogen atom, a hydrogen molecule, a water molecule, a nitrogen atom, a nitrogen molecule, a nitrogen oxide molecule (e.g., N₂O, NO, and NO₂), and a copper atom. Alternatively, the conductor 560a is preferably formed using a conductive material having a function of inhibiting diffusion of oxygen (e.g., at least one of oxygen atoms, oxygen molecules, and the like). When the conductor 560a has a function of inhibiting diffusion of oxygen, the conductivity of the conductor 560b can be prevented from being lowered because of oxidization due to oxygen included in the insulator 545. As a conductive material having a function of inhibiting diffusion of oxygen, for example, tantalum, tantalum nitride, ruthenium, ruthenium oxide, or the like is preferably used. The conductor 560a can be formed using an oxide semiconductor that can be used for the oxide 530. In that case, when the conductor 560b is formed by a sputtering method, the conductor 560a can have a reduced electric resistance and become a conductor. Such a conductor can be referred to as an OC (Oxide Conductor) electrode.

Furthermore, the conductor 560b is preferably formed using a conductive material including tungsten, copper, or aluminum as its main component. The conductor 560b also functions as a wiring and thus is preferably a conductor having high conductivity. For example, a conductive material including tungsten, copper, or aluminum as its main component can be used. The conductor 560b may have a stacked-layer structure, for example, a stacked-layer structure of titanium or titanium nitride and any of the above conductive materials.

The insulator 580 is provided over the conductor 542a and the conductor 542b with the insulator 544 positioned therebetween. The insulator 580 preferably includes an excess-oxygen region. For example, the insulator 580 preferably includes silicon oxide, silicon oxynitride, silicon nitride oxide, silicon nitride, silicon oxide to which fluorine is added, silicon oxide to which carbon is added, silicon oxide to which carbon and nitrogen are added, porous silicon oxide, a resin, or the like. In particular, silicon oxide and silicon oxynitride, which have thermal stability, are preferable. Silicon oxide and porous silicon oxide are particularly preferable because an excess-oxygen region can be formed easily in a later step.

The insulator 580 preferably includes an excess-oxygen region. When the insulator 580 from which oxygen is released by heating is provided, oxygen in the insulator 580 can be efficiently supplied to the oxide 530. The concentration of impurities such as water and hydrogen in the insulator 580 is preferably lowered.

The opening of the insulator 580 is formed to overlap with a region between the conductor 542a and the conductor 542b. Thus, the conductor 560 is formed to be embedded in the opening of the insulator 580 and the region sandwiched between the conductor 542a and the conductor 542b.

The gate length needs to be short for miniaturization of the semiconductor device without a reduction in the conductivity of the conductor 560. When the conductor 560 is made thick to achieve this, the conductor 560 might have a shape with a high aspect ratio. Even when having a shape with a high aspect ratio, the conductor 560 can be formed without collapsing during the process because the conductor 560 is provided to be embedded in the opening of the insulator 580 in this embodiment.

The insulator 574 is preferably provided in contact with the top surfaces of the insulator 580, the conductor 560, and the insulator 545. When the insulator 574 is formed by a sputtering method, the insulator 545 and the insulator 580 can include an excess-oxygen region. Thus, oxygen can be supplied from the excess-oxygen region to the oxide 530.

For example, a metal oxide including one or two or more of hafnium, aluminum, gallium, yttrium, zirconium, tungsten, titanium, tantalum, nickel, germanium, magnesium, and the like can be used as the insulator 574.

In particular, aluminum oxide has a high barrier property, and even a thin aluminum oxide film having a thickness greater than or equal to 0.5 nm and less than or equal to 3.0 nm can inhibit diffusion of hydrogen and nitrogen. Thus, aluminum oxide deposited by a sputtering method can serve as not only an oxygen supply source but also a barrier film against impurities such as hydrogen.

The insulator 581 functioning as an interlayer film is preferably provided over the insulator 574. As in the insulator 524 or the like, the concentration of impurities such as water and hydrogen in the insulator 581 is preferably lowered.

A conductor 540a and a conductor 540b are provided in the openings formed in the insulator 581, the insulator 574, the insulator 580, and the insulator 544. The conductor 540a and the conductor 540b are provided to face each other with the conductor 560 positioned therebetween. The conductor 540a and the conductor 540b have a structure similar to that of a conductor 546 and a conductor 548 described later.

An insulator 582 is provided over the insulator 581. A material having a barrier property against oxygen, hydrogen, or the like is preferably used for the insulator 582. Thus, the insulator 582 can be formed using a material similar to that for the insulator 514. For the insulator 582, a metal oxide such as aluminum oxide, hafnium oxide, or tantalum oxide is preferably used, for example.

In particular, aluminum oxide has an excellent blocking effect that prevents permeation of oxygen and impurities such as hydrogen and moisture that cause a change in electrical characteristics of the transistor. Accordingly, the use of aluminum oxide can prevent entry of impurities such as hydrogen and moisture into the transistor 500 during and after a manufacturing process of the transistor. In addition, release of oxygen from the oxide included in the transistor 500 can be prevented. Thus, aluminum oxide is suitably used for a protective film of the transistor 500.

An insulator 586 is provided over the insulator 582. The insulator 586 can be formed using a material similar to that for the insulator 320. In the case where a material with a relatively low dielectric constant is used for these insulators, the parasitic capacitance between wirings can be reduced. For example, a silicon oxide film, a silicon oxynitride film, or the like can be used for the insulator 586.

The conductor 546, the conductor 548, and the like are embedded in the insulator 520, the insulator 522, the insulator 524, the insulator 544, the insulator 580, the insulator 574, the insulator 581, the insulator 582, and the insulator 586.

The conductor 546 and the conductor 548 function as plugs or wirings that are connected to the capacitor 600, the transistor 500, or the transistor 550. The conductor 546 and the conductor 548 can be formed using a material similar to that for the conductor 328 and the conductor 330.

After the transistor 500 is formed, an opening may be formed to surround the transistor 500 and an insulator having a high barrier property against hydrogen or water may be formed to cover the opening. Surrounding the transistor 500 by the insulator having a high barrier property can prevent entry of moisture and hydrogen from the outside. Alternatively, a plurality of transistors 500 may be collectively surrounded by the insulator having a high barrier property against hydrogen or water. When an opening is formed to surround the transistor 500, for example, the formation of an opening reaching the insulator 522 or the insulator 514 and the formation of the insulator having a high barrier property in contact with the insulator 522 or the insulator 514 are suitable because these formation steps can also serve as some of the manufacturing steps of the transistor 500. The insulator having a high barrier property against hydrogen or water is formed using a material similar to that for the insulator 522 or the insulator 514, for example.

The capacitor 600 is provided above the transistor 500. The capacitor 600 includes a conductor 610, a conductor 620, and an insulator 630.

A conductor 612 may be provided over the conductor 546 and the conductor 548. The conductor 612 functions as a plug or a wiring that is connected to the transistor 500. The conductor 610 functions as an electrode of the capacitor 600. The conductor 612 and the conductor 610 can be formed at the same time.

The conductor 612 and the conductor 610 can be formed using a metal film including an element selected from molybdenum, titanium, tantalum, tungsten, aluminum, copper, chromium, neodymium, and scandium; a metal nitride film including any of the above elements as its component (a tantalum nitride film, a titanium nitride film, a molybdenum nitride film, or a tungsten nitride film); or the like. Alternatively, it is possible to use a conductive material such as indium tin oxide, indium oxide including tungsten oxide, indium zinc oxide including tungsten oxide, indium oxide including titanium oxide, indium tin oxide including titanium oxide, indium zinc oxide, or indium tin oxide to which silicon oxide is added.

The conductor 612 and the conductor 610 each have a single-layer structure in this embodiment; however, the structure is not limited thereto, and a stacked-layer structure of two or more layers may be used. For example, between a conductor having a barrier property and a conductor having high conductivity, a conductor that is highly adhesive to the conductor having a barrier property and the conductor having high conductivity may be formed.

The conductor 620 is provided to overlap with the conductor 610 with the insulator 630 positioned therebetween. Note that the conductor 620 can be formed using a conductive material such as a metal material, an alloy material, or a metal oxide material. It is preferable to use a high-melting-point material that has both heat resistance and conductivity, such as tungsten or molybdenum, and it is particularly preferable to use tungsten. In the case where the conductor 620 is formed concurrently with another component such as a conductor, copper (Cu), aluminum (Al), or the like, which is a low-resistance metal material, is used.

An insulator 640 is provided over the conductor 620 and the insulator 630. The insulator 640 can be formed using a material similar to that for the insulator 320. The insulator 640 may function as a planarization film that covers a roughness thereunder.

With the use of the structure, a semiconductor device that includes a transistor including an oxide semiconductor can be miniaturized or highly integrated.

Examples of a substrate that can be used for the semiconductor device of one embodiment of the present invention include a glass substrate, a quartz substrate, a sapphire substrate, a ceramic substrate, a metal substrate (e.g., a stainless steel substrate, a substrate including stainless steel foil, a tungsten substrate, and a substrate including tungsten foil), a semiconductor substrate (e.g., a single crystal semiconductor substrate, a polycrystalline semiconductor substrate, and a compound semiconductor substrate), and a SOI (Silicon on Insulator) substrate. Alternatively, a plastic substrate having heat resistance to the processing temperature in this embodiment may be used. Examples of a glass substrate include a barium borosilicate glass substrate, an aluminosilicate glass substrate, an aluminoborosilicate glass substrate, and a soda lime glass substrate. Alternatively, crystallized glass or the like can be used.

Alternatively, a flexible substrate, an attachment film, paper including a fibrous material, a base film, or the like can be used as the substrate. Examples of a material for a flexible substrate, an attachment film, a base film, or the like include plastic typified by polyethylene terephthalate (PET), polyethylene naphthalate (PEN), polyether sulfone (PES), and polytetrafluoroethylene (PTFE). Another example is a synthetic resin such as acrylic. Other examples include polypropylene, polyester, polyvinyl fluoride, and polyvinyl chloride. Alternatively, polyamide, polyimide, an aramid resin, an epoxy resin, an inorganic vapor deposition film, and paper can be used. Specifically, the use of a semiconductor substrate, a single crystal substrate, an SOI substrate, or the like enables the manufacture of small-sized transistors with a small variation in characteristics, size, shape, or the like and with high current capability. A circuit using such transistors achieves lower power consumption or higher integration.

A flexible substrate may be used as the substrate, and a transistor, a resistor, a capacitor, and/or the like may be formed directly over the flexible substrate. Alternatively, a separation layer may be provided between the substrate and the transistor, the resistor, the capacitor, and/or the like. The separation layer can be used when part or the whole of a semiconductor device formed over the separation layer is separated from the substrate and transferred to another substrate. In such a case, the transistor, the resistor, the capacitor, and/or the like can be transferred to a substrate having low heat resistance, a flexible substrate, or the like. As the separation layer, a stack of inorganic films, namely a tungsten film and a silicon oxide film, an organic resin film of polyimide or the like formed over a substrate, or a silicon film including hydrogen can be used, for example.

That is, a semiconductor device may be formed over one substrate and then transferred to another substrate. Examples of a substrate to which a semiconductor device is transferred include, in addition to the above-described substrates over which transistors can be formed, a paper substrate, a cellophane substrate, an aramid film substrate, a polyimide film substrate, a stone substrate, a wood substrate, a cloth substrate (including a natural fiber (e.g., silk, cotton, or hemp), a synthetic fiber (e.g., nylon, polyurethane, or polyester), a regenerated fiber (e.g., acetate, cupro, rayon, or regenerated polyester), or the like), a leather substrate, and a rubber substrate. With the use of any of these substrates, a flexible semiconductor device or a highly durable semiconductor device can be manufactured, high heat resistance can be provided, or a reduction in weight or thickness can be achieved.

Providing a semiconductor device over a flexible substrate can suppress an increase in weight and can produce a non-breakable semiconductor device.

Note that the transistor 550 illustrated in FIG. 8 is just an example and is not limited to the structure illustrated therein, and an appropriate transistor can be used in accordance with a circuit structure, a driving method, or the like. For example, when the semiconductor device is a single-polarity circuit using only OS transistors (which mean transistors having the same polarity, e.g., only n-channel transistors), the transistor 550 has a structure similar to that of the transistor 500.

The configuration, structure, method, and the like described in this embodiment can be used in appropriate combination with the configurations, structures, methods, and the like described in the other embodiments, examples, and the like.

### Embodiment 4

In this embodiment, cross-sectional structure examples of a semiconductor device including OS transistors, which is a DOSRAM or a NOSRAM and described in the above embodiments, are described.

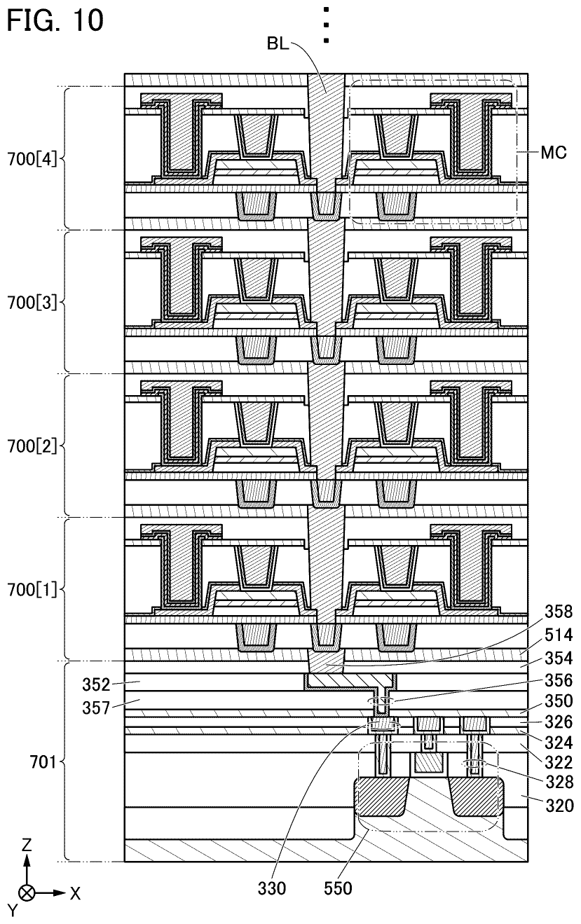

FIG. 10 illustrates a cross-sectional structure example of the case of using a DOSRAM circuit structure. In the example illustrated in FIG. 10, an element layer 700[1] to an element layer 700[4] are stacked over a driver circuit layer 701.

FIG. 10 illustrates the transistor 550 included in the driver circuit layer 701 as an example. The transistor 550 described in the above embodiment can be used as the transistor 550.

The transistor 550 illustrated in FIG. 10 is just an example and is not limited to the structure illustrated therein, and an appropriate transistor can be used in accordance with a circuit structure or a driving method.

A wiring layer provided with an interlayer film, a wiring, a plug, and the like may be provided between the driver circuit layer 701 and the element layers 700 or between a k-th element layer 700 and a (k+1)-th element layer 700. In this embodiment and the like, the k-th element layer 700 is referred to as the element layer 700[k], and the (k+1)-th element layer 700 is referred to as the element layer 700[k+1], in some cases. Here, k is an integer greater than or equal to 1 and less than or equal to N. In this embodiment and the like, the solutions of “k+α (α is an integer greater than or equal to 1)” and “k−α” are each an integer greater than or equal to 1 and less than or equal to N.

A plurality of wiring layers can be provided in accordance with the design. Furthermore, in this specification and the like, a wiring and a plug electrically connected to the wiring may be a single component. That is, part of a conductor functions as a wiring in some cases, and part of a conductor functions as a plug in other cases.

For example, the insulator 320, the insulator 322, the insulator 324, and the insulator 326 are stacked in this order over the transistor 550 as interlayer films. The conductor 328 or the like is embedded in the insulator 320 and the insulator 322. The conductor 330 or the like is embedded in the insulator 324 and the insulator 326. Note that the conductor 328 and the conductor 330 each function as a contact plug or a wiring.

The insulator functioning as an interlayer film may function as a planarization film that covers a roughness thereunder. For example, the top surface of the insulator 320 may be planarized by planarization treatment using a chemical mechanical polishing (CMP) method or the like to increase the level of planarity.

A wiring layer may be provided over the insulator 326 and the conductor 330. For example, in FIG. 10, the insulator 350, an insulator 357, the insulator 352, and the insulator 354 are stacked in this order over the insulator 326 and the conductor 330. The conductor 356 is formed in the insulator 350, the insulator 357, and the insulator 352. The conductor 356 functions as a contact plug or a wiring.

Over the insulator 354, the insulator 514 included in the element layer 700[1] is provided. A conductor 358 is embedded in the insulator 514 and the insulator 354. The conductor 358 functions as a contact plug or a wiring. For example, a bit line BL and the transistor 550 are electrically connected to each other through the conductor 358, the conductor 356, the conductor 330, and the like.

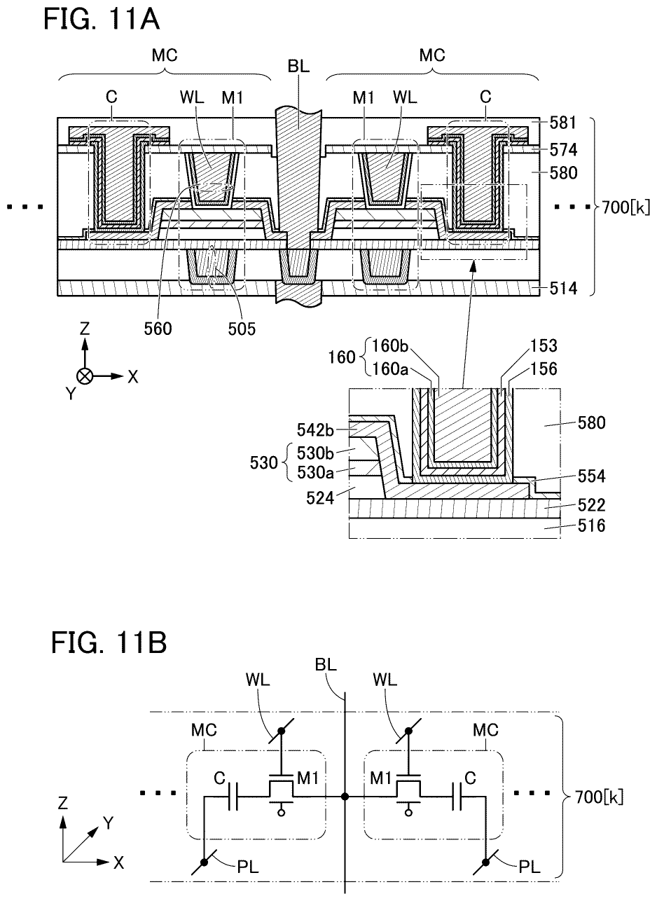

FIG. 11A illustrates a cross-sectional structure example of the element layer 700[k]. FIG. 11B is an equivalent circuit diagram of FIG. 11A. FIG. 11A illustrates an example where two memory cells MC are electrically connected to one bit line BL.

The memory cell MC illustrated in FIG. 10 and FIG. 11A includes the transistor MI and the capacitor C. As the transistor M1, the transistor 500 described in the above embodiment can be used.

In this embodiment, a variation of the transistor 500 is illustrated as the transistor M1. Specifically, the transistor MI is different from the transistor 500 in that the conductor 542a and the conductor 542b extend beyond an edge of a metal oxide 531.

The memory cell MC illustrated in FIG. 10 and FIG. 11A includes a conductor 156 functioning as one terminal of the capacitor C, an insulator 153 functioning as a dielectric, and a conductor 160 (a conductor 160a and a conductor 160b) functioning as the other terminal of the capacitor C. The conductor 156 is electrically connected to part of the conductor 542b. The conductor 160 is electrically connected to the wiring PL (not shown in FIG. 11A).

The capacitor C is formed in an opening portion that is provided by removal of part of the insulator 574, part of the insulator 580, and part of an insulator 554. Since the conductor 156, the insulator 580, and the insulator 554 are formed along a side surface of the opening portion, the conductor 156, the insulator 580, and the insulator 554 are preferably formed by an ALD method, a CVD method, or the like.

The conductor 156 and the conductor 160 may be formed using a conductor that can be used for a conductor 505 or the conductor 560. For example, the conductor 156 may be formed using titanium nitride by an ALD method. The conductor 160a may be formed using titanium nitride by an ALD method, and the conductor 160b may be formed using tungsten by a CVD method. Note that in the case where the adhesion of tungsten to the insulator 153 is sufficiently high, a single-layer film of tungsten formed by a CVD method may be used as the conductor 160.

For the insulator 153, an insulator of a high dielectric constant (high-k) material (material with a high relative permittivity) is preferably used. As the insulator of high dielectric constant material, an oxide, an oxynitride, a nitride oxide, or a nitride including one or more kinds of metal element selected from aluminum, hafnium, zirconium, gallium, and the like can be used, for example. The above-described oxide, oxynitride, nitride oxide, and nitride may include silicon. Insulating layers each formed of any of the above-described materials can be stacked to be used.

As the insulator of high dielectric constant material, aluminum oxide, hafnium oxide, zirconium oxide, an oxide including aluminum and hafnium, an oxynitride including aluminum and hafnium, an oxide including silicon and hafnium, an oxynitride including silicon and hafnium, an oxide including silicon and zirconium, an oxynitride including silicon and zirconium, an oxide including hafnium and zirconium, an oxynitride including hafnium and zirconium, or the like can be used, for example. Using such a high dielectric constant material allows the insulator 153 to be thick enough to inhibit a leakage current and a sufficiently high capacitance of the capacitor C to be ensured.

It is preferable to use stacked insulating layers each formed of any of the above-described materials. A stacked-layer structure using a high dielectric constant material and a material having higher dielectric strength than the high dielectric constant material is preferably used. For example, as the insulator 153, an insulating film in which zirconium oxide, aluminum oxide, and zirconium oxide are stacked in this order can be used. An insulating film in which zirconium oxide, aluminum oxide, zirconium oxide, and aluminum oxide are stacked in this order can be used, for example. An insulating film in which hafnium zirconium oxide, aluminum oxide, hafnium zirconium oxide, and aluminum oxide are stacked in this order can be used, for example. The stacking of such an insulator having relatively high dielectric strength, such as aluminum oxide, can increase the dielectric strength and inhibit electrostatic breakdown of the capacitor C.

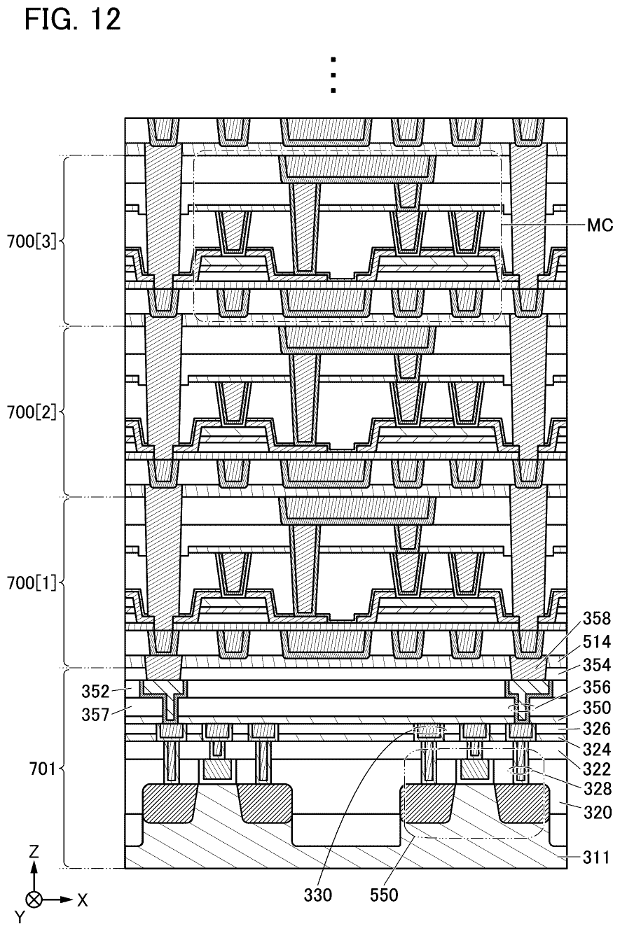

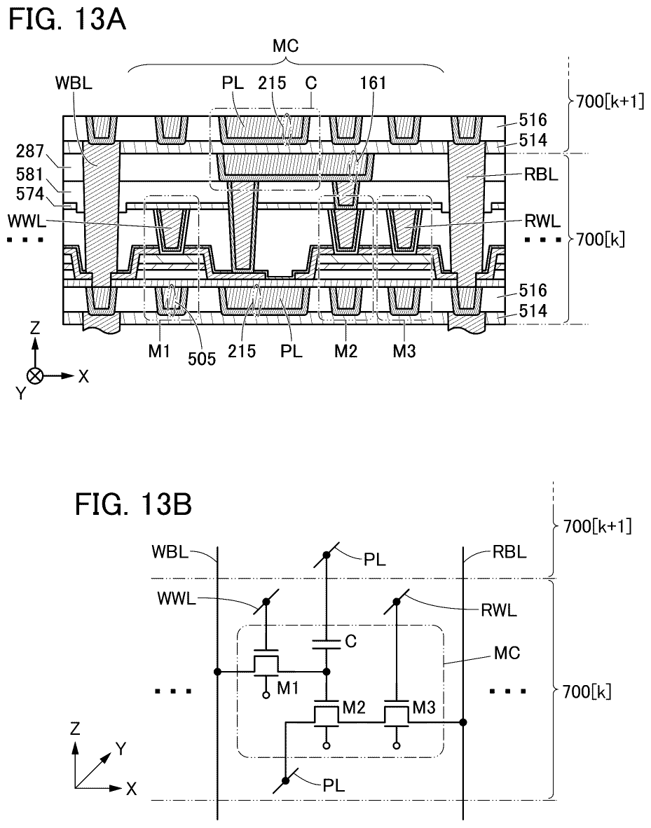

FIG. 12 illustrates a cross-sectional structure example of the case of using a NOSRAM memory cell circuit structure. FIG. 12 is also a variation of FIG. 10. FIG. 13A illustrates a cross-sectional structure example of the element layer 700[k]. FIG. 13B is an equivalent circuit diagram of FIG. 13A.

The memory cell MC illustrated in FIG. 12 and FIG. 13A includes the transistor MI, the transistor M2, and the transistor M3 over the insulator 514. A conductor 215 is provided over the insulator 514. The conductor 215 can be formed using the same material in the same process as those of the conductor 505 at the same time.

The transistor M2 and the transistor M3 illustrated in FIG. 12 and FIG. 13A share one island-shaped metal oxide 531. In other words, a part of the one island-shaped metal oxide 531 functions as a channel formation region of the transistor M2, and another part thereof functions as a channel formation region of the transistor M3. Furthermore, the source of the transistor M2 and a drain of the transistor M3 are shared, or the drain of the transistor M2 and a source of the transistor M3 are shared. Thus, the area occupied by the transistors M2 and M3 is smaller than that of the case where the transistors M2 and M3 are independently provided.

In the memory cell MC illustrated in FIG. 12 and FIG. 13A, an insulator 287 is provided over the insulator 581, and a conductor 161 is embedded in the insulator 287. The insulator 514 of the element layer 700[k+1] is provided over the insulator 287 and the conductor 161.

In FIG. 12 and FIG. 13A, the conductor 215 of the element layer 700[k+1] functions as one terminal of the capacitor C, the insulator 514 of the element layer 700[k+1] functions as a dielectric of the capacitor C, and the conductor 161 functions as the other terminal of the capacitor C. The other of the source and the drain of the transistor MI is electrically connected to the conductor 161 via a contact plug, and the gate of the transistor M2 is electrically connected to the conductor 161 via another contact plug.

This embodiment can be implemented in combination with the other embodiments described in this specification as appropriate.

### Embodiment 5

In this embodiment, a transistor including an oxide semiconductor in a channel formation region (OS transistor) is described. In the description of the OS transistor, comparison with a transistor including silicon in a channel formation region (also referred to as a Si transistor) is also described simply.

### [OS Transistor]

An oxide semiconductor having a low carrier concentration is preferably used for an OS transistor. For example, the carrier concentration in an oxide semiconductor in the channel formation region is lower than or equal to 1×10¹⁸ cm⁻³, preferably lower than 1×10¹⁷ cm⁻³, further preferably lower than 1×10¹⁶ cm⁻³, still further preferably lower than 1×10¹³ cm⁻³, yet further preferably lower than 1×10¹⁰ cm⁻³, and higher than or equal to 1×10⁻⁹ cm⁻³. In order to reduce the carrier concentration in an oxide semiconductor film, the impurity concentration in the oxide semiconductor film is reduced so that the density of defect states can be reduced. In this specification and the like, a state with a low impurity concentration and a low density of defect states is referred to as a highly purified intrinsic or substantially highly purified intrinsic state. Note that an oxide semiconductor having a low carrier concentration may be referred to as a highly purified intrinsic or substantially highly purified intrinsic oxide semiconductor.

A highly purified intrinsic or substantially highly purified intrinsic oxide semiconductor has a low density of defect states and thus has a low density of trap states in some cases. Charge trapped by the trap states in the oxide semiconductor takes a long time to disappear and might behave like fixed charge. Thus, a transistor whose channel formation region is formed in an oxide semiconductor with a high density of trap states has unstable electrical characteristics in some cases.

Accordingly, in order to obtain stable electrical characteristics of a transistor, reducing the impurity concentration in an oxide semiconductor is effective. In order to reduce the impurity concentration in the oxide semiconductor, it is preferable that the impurity concentration in an adjacent film be also reduced. Examples of the impurity include hydrogen and nitrogen. Note that an impurity in an oxide semiconductor refers to, for example, elements other than the main components of the oxide semiconductor. For example, an element with a concentration lower than 0.1 atomic % can be regarded as an impurity.

An OS transistor is likely to have its electrical characteristics changed when impurities and oxygen vacancies exist in a channel formation region of the oxide semiconductor, which might affect the reliability. In some cases, a defect that is an oxygen vacancy into which hydrogen enters (hereinafter sometimes referred to as VoH) is formed in the oxide semiconductor of the OS transistor, which generates an electron serving as a carrier. Formation of VoH in the channel formation region may increase the donor concentration in the channel formation region. An increase in the donor concentration in the channel formation region may lead to a variation in threshold voltage. Thus, when the channel formation region in the oxide semiconductor includes oxygen vacancies, the transistor is likely to have normally-on characteristics (characteristics with which, even when no voltage is applied to the gate electrode, the channel exists and current flows through the transistor). Thus, impurities, oxygen vacancies, and VoH are preferably reduced as much as possible in the channel formation region in the oxide semiconductor.

The band gap of the oxide semiconductor is preferably wider than the band gap of silicon (typically 1.1 eV), further preferably greater than or equal to 2 eV, still further preferably greater than or equal to 2.5 eV, yet still further preferably greater than or equal to 3.0 eV. With use of an oxide semiconductor having a wider band gap than silicon, the off-state current of the transistor (also referred to as Ioff) can be reduced.

In a Si transistor, a short-channel effect (also referred to as SCE) appears as miniaturization of the transistor proceeds. This hinders miniaturization of a Si transistor. One factor in causing the short-channel effect is a narrow band gap of silicon. By contrast, the OS transistor includes an oxide semiconductor that is a semiconductor material having a wide band gap, and thus can suppress the short-channel effect. In other words, the short-channel effect does not appear or hardly appears in the OS transistor.

The short-channel effect refers to degradation of electrical characteristics that becomes obvious along with miniaturization of a transistor (a decrease in channel length). Specific examples of the short-channel effect include a decrease in threshold voltage, an increase in subthreshold swing value (sometimes referred to as S value), and an increase in leakage current. Here, the S value refers to the amount of change in a gate voltage which makes the drain current change by one digit in a subthreshold region at a constant drain voltage.

The characteristic length is widely used as an indicator of resistance to a short-channel effect. The characteristic length is an indicator of curving of a potential in a channel formation region. The smaller the characteristic length is, the more sharply the potential rises; thus, a smaller characteristic length indicates higher resistance to a short-channel effect.

The OS transistor is an accumulation-type transistor and the Si transistor is an inversion-type transistor. Accordingly, an OS transistor has a shorter characteristic length between a source region and a channel formation region and a shorter characteristic length between a drain region and the channel formation region than a Si transistor. Thus, the OS transistor has higher resistance to a short-channel effect than the Si transistor. That is, the OS transistor is more suitable than the Si transistor in the case where a short-channel transistor is to be formed.

Even in the case where the carrier concentration in the oxide semiconductor is reduced until the channel formation region becomes an i-type or substantially i-type region, the conduction band minimum of the channel formation region in a short-channel transistor decreases because of the conduction band lowering (CBL) effect; thus, there is a possibility that a difference in energy of the conduction band minimum between the channel formation region and the source region or the drain region is as small as 0.1 eV or more and 0.2 eV or less. Accordingly, the OS transistor can be regarded as having an n⁺/n⁻/n⁺ accumulation-type junction-less transistor structure or an n⁺/n⁻/n⁺ accumulation-type non-junction transistor structure in which the channel formation region becomes an n⁻-type region and the source region and the drain region become n⁺-type regions in the OS transistor.

An OS transistor having the above structure enables a semiconductor device to have favorable electrical characteristics even when the semiconductor device is miniaturized or highly integrated. For example, the semiconductor device can have favorable electrical characteristics even when the OS transistor has a gate length less than or equal to 20 nm, less than or equal to 15 nm, less than or equal to 10 nm, less than or equal to 7 nm, or less than or equal to 6 nm and greater than or equal to 1 nm, greater than or equal to 3 nm, or greater than or equal to 5 nm. By contrast, it is sometimes difficult for the Si transistor to have a gate length less than or equal to 20 nm or less than or equal to 15 nm because of a short-channel effect. Thus, the OS transistor can be more suitably used as a short-channel transistor than the Si transistor. Note that the gate length refers to the length of a gate electrode in a direction in which carriers move inside a channel formation region during operation of the transistor and to the width of the bottom surface of the gate electrode in a plan view of the transistor.

Miniaturization of an OS transistor can improve the high frequency characteristics of the transistor. Specifically, the cutoff frequency of the transistor can be improved. When the gate length of the OS transistor is within the above range, the cutoff frequency of the transistor can be greater than or equal to 50 GHz, preferably greater than or equal to 100 GHz, further preferably greater than or equal to 150 GHz at room temperature, for example.

As described above, an OS transistor has an effect superior to that of a Si transistor, such as a low off-state current and capability of having a short channel length.

The configuration, structure, method, or the like described in this embodiment can be used in combination with the configuration, structure, method, or the like described in the other embodiments and the like as appropriate.

### Embodiment 6

This embodiment describes an electronic component, an electronic device, a large computer, space equipment, and a data center (also referred to as DC) that can include any of the semiconductor devices described in the above embodiments. Electronic components, electronic devices, a large computer, space equipment, and a data center in which the semiconductor device of one embodiment of the present invention is used are effective in improving performance, e.g., reducing power consumption.

### [Electronic Component]

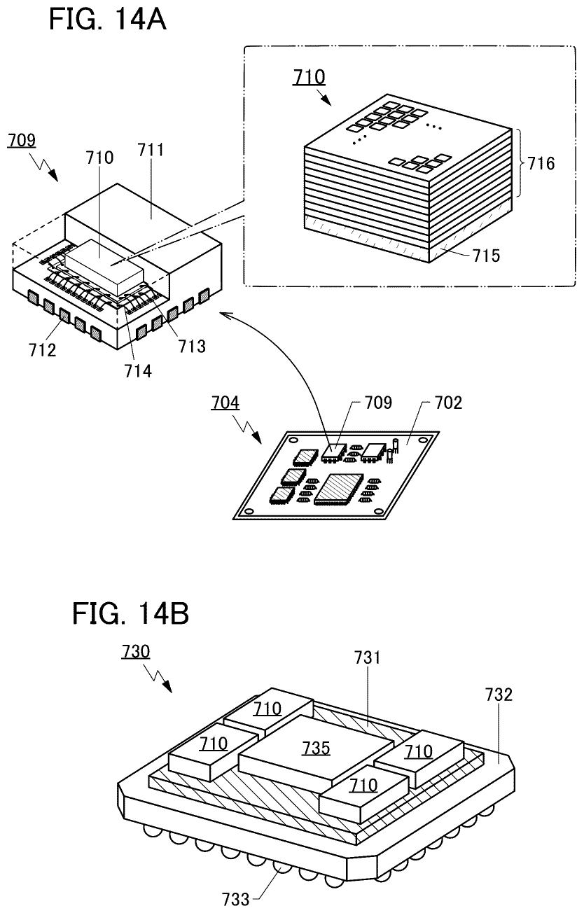

FIG. 14A is a perspective view of a substrate (a circuit board 704) provided with an electronic component 709. The electronic component 709 illustrated in FIG. 14A includes a semiconductor device 710 in a mold 711. FIG. 14A omits illustrations of some parts to show the inside of the electronic component 709. The electronic component 709 includes a land 712 outside the mold 711. The land 712 is electrically connected to an electrode pad 713, and the electrode pad 713 is electrically connected to the semiconductor device 710 via a wire 714. The electronic component 709 is mounted on a printed circuit board 702, for example. A plurality of such electronic components are combined and electrically connected to each other on the printed circuit board 702, so that the circuit board 704 is completed.

The semiconductor device 710 includes a driver circuit layer 715 and a memory layer 716. The memory layer 716 has a structure where a plurality of memory cell arrays are stacked. A stacked-layer structure of the driver circuit layer 715 and the memory layer 716 can be a monolithic stacked-layer structure. In the monolithic stacked-layer structure, layers can be connected to each other without using a through electrode technique such as a through silicon via (TSV) and a bonding technique such as Cu-to-Cu direct bonding. The monolithic stacked-layer structure of the driver circuit layer 715 and the memory layer 716 enables, for example, what is called an on-chip memory structure where a memory is directly formed on a processor. The on-chip memory structure allows an interface portion between the processor and the memory to operate at high speed.

With the on-chip memory structure, the sizes of a connection wiring and the like can be smaller than those in the case where the through electrode technique such as TSV is employed; thus, the number of connection pins can be increased. The increase in the number of connection pins enables parallel operations, which can improve the bandwidth of the memory (also referred to as a memory bandwidth).

It is preferable that the plurality of memory cell arrays included in the memory layer 716 be formed with OS transistors and be monolithically stacked. Monolithically stacking the plurality of memory cell arrays can improve one or both of a memory bandwidth and a memory access latency. Note that the bandwidth refers to the data transfer volume per unit time, and the access latency refers to a period of time from data access to the start of data transmission. Note that in the case where the memory layer 716 is formed with Si transistors, the monolithic stacked-layer structure is difficult to form as compared with the case where the memory layer 716 is formed with OS transistors. Thus, an OS transistor is superior to a Si transistor in the monolithic stacked-layer structure.

The semiconductor device 710 may be called a die. Note that in this specification and the like, a die refers to a chip obtained by, for example, forming a circuit pattern on a disc-like substrate (also referred to as a wafer) or the like and cutting the substrate with the pattern into dices in a process of manufacturing a semiconductor chip. Examples of semiconductor materials that can be used for the die include silicon (Si), silicon carbide (SiC), and gallium nitride (GaN). For example, a die obtained from a silicon substrate (also referred to as a silicon wafer) is referred to as a silicon die in some cases.

FIG. 14B is a perspective view of an electronic component 730. The electronic component 730 is an example of a SiP (System in Package) or an MCM (Multi Chip Module). In the electronic component 730, an interposer 731 is provided on a package substrate 732 (a printed circuit board), and a semiconductor device 735 and a plurality of semiconductor devices 710 are provided on the interposer 731.

The electronic component 730 using the semiconductor devices 710 as high bandwidth memory (HBM) is illustrated as an example. The semiconductor device 735 can be used for an integrated circuit such as a CPU (Central Processing Unit), a GPU (Graphics Processing Unit), or an FPGA (Field Programmable Gate Array).

As the package substrate 732, for example, a ceramic substrate, a plastic substrate, or a glass epoxy substrate can be used. As the interposer 731, for example, a silicon interposer or a resin interposer can be used.

The interposer 731 includes a plurality of wirings and has a function of electrically connecting a plurality of integrated circuits with different terminal pitches. The plurality of wirings are provided in a single layer or multiple layers. The interposer 731 has a function of electrically connecting an integrated circuit provided over the interposer 731 to an electrode provided over the package substrate 732. Accordingly, the interposer is sometimes referred to as a “redistribution substrate” or an “intermediate substrate”. A through electrode may be provided in the interposer 731 to be used for electrically connecting the integrated circuit and the package substrate 732. Moreover, in the case of using a silicon interposer, a TSV can also be used as the through electrode.

In order to achieve a wide memory bandwidth, many wirings need to be connected to an HBM. Thus, formation of minute and high-density wirings is required for an interposer on which an HBM is mounted. For this reason, a silicon interposer is preferably used as the interposer on which an HBM is mounted.

In a SiP, an MCM, and the like using a silicon interposer, a decrease in reliability due to a difference in expansion coefficient between an integrated circuit and the interposer is less likely to occur. Furthermore, a surface of a silicon interposer has high planarity, so that a poor connection between the silicon interposer and an integrated circuit provided over the silicon interposer is less likely to occur. It is particularly preferable to use a silicon interposer for a 2.5D package (2.5-dimensional mounting) in which a plurality of integrated circuits are arranged side by side over the interposer.

In the case where a plurality of integrated circuits with different terminal pitches are electrically connected with use of a silicon interposer, a TSV, and the like, a space for a width of the terminal pitch and the like is needed. Accordingly, in the case where the size of the electronic component 730 is reduced, the width of the terminal pitch becomes an issue, which sometimes makes it difficult to provide a large number of wirings for obtaining a wide memory bandwidth. For this reason, the monolithic stacked-layer structure using the OS transistors is suitable. A composite structure combining memory cell arrays stacked using TSV and monolithically stacked memory cell arrays may be employed.

A heat sink (radiator plate) may be provided to overlap with the electronic component 730. In the case of providing a heat sink, the heights of integrated circuits provided over the interposer 731 are preferably the same. For example, in the electronic component 730 described in this embodiment, the heights of the semiconductor devices 710 and the semiconductor device 735 are preferably equal to each other.

An electrode 733 may be provided on the bottom portion of the package substrate 732 to mount the electronic component 730 on another substrate. FIG. 14B illustrates an example in which the electrode 733 is formed of a solder ball. Solder balls are provided in a matrix on the bottom portion of the package substrate 732, whereby BGA (Ball Grid Array) mounting can be achieved. Alternatively, the electrode 733 may be formed of a conductive pin. When conductive pins are provided in a matrix on the bottom portion of the package substrate 732, PGA (Pin Grid Array) mounting can be achieved.

The electronic component 730 can be mounted on another substrate by various mounting methods not limited to BGA and PGA. Examples of a mounting method include SPGA (Staggered Pin Grid Array), LGA (Land Grid Array), QFP (Quad Flat Package), QFJ (Quad Flat J-leaded package), and QFN (Quad Flat Non-leaded package).

### [Electronic Device]

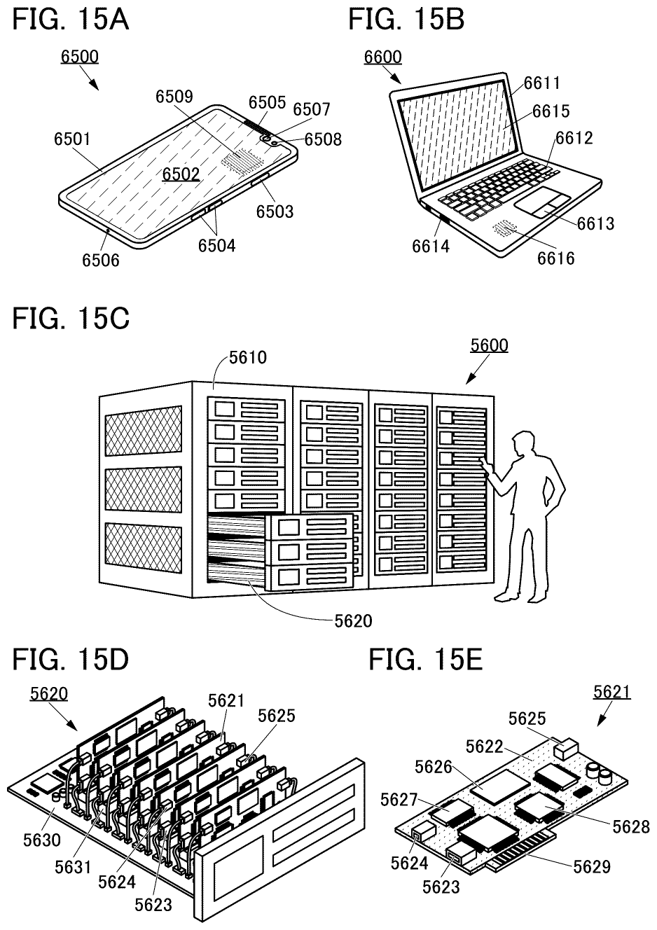

FIG. 15A is a perspective view of an electronic device 6500. The electronic device 6500 illustrated in FIG. 15A is a portable information terminal that can be used as a smartphone. The electronic device 6500 includes a housing 6501, a display portion 6502, a power button 6503, buttons 6504, a speaker 6505, a microphone 6506, a camera 6507, a light source 6508, a control device 6509, and the like. The control device 6509 includes one or more selected from a CPU, a GPU, and a memory device, for example. The semiconductor device of one embodiment of the present invention can be used for the display portion 6502, the control device 6509, and the like.

An electronic device 6600 illustrated in FIG. 15B is an information terminal that can be used as a laptop personal computer. The electronic device 6600 includes a housing 6611, a keyboard 6612, a pointing device 6613, an external connection port 6614, a display portion 6615, a control device 6616, and the like. The control device 6616 includes one or more selected from a CPU, a GPU, and a memory device, for example. The semiconductor device of one embodiment of the present invention can be used for the display portion 6615, the control device 6616, and the like. Note that the semiconductor device of one embodiment of the present invention is preferably used for the control device 6509 and the control device 6616, in which case power consumption can be reduced.

### [Large Computer]

FIG. 15C is a perspective view of a large computer 5600. In the large computer 5600 illustrated in FIG. 15C, a plurality of rack mount computers 5620 are stored in a rack 5610. Note that the large computer 5600 may be referred to as a supercomputer.

The computer 5620 can have a structure in a perspective view illustrated in FIG. 15D, for example. In FIG. 15D, the computer 5620 includes a motherboard 5630, and the motherboard 5630 includes a plurality of slots 5631 and a plurality of connection terminals. A PC card 5621 is inserted in the slot 5631. In addition, the PC card 5621 includes a connection terminal 5623, a connection terminal 5624, and a connection terminal 5625, each of which is connected to the motherboard 5630.

The PC card 5621 illustrated in FIG. 15E is an example of a processing board provided with a CPU, a GPU, a memory device, and the like. The PC card 5621 includes a board 5622. The board 5622 includes the connection terminal 5623, the connection terminal 5624, the connection terminal 5625, a semiconductor device 5626, a semiconductor device 5627, a semiconductor device 5628, and a connection terminal 5629. Although FIG. 15E illustrates semiconductor devices other than the semiconductor device 5626, the semiconductor device 5627, and the semiconductor device 5628, the following description of the semiconductor device 5626, the semiconductor device 5627, and the semiconductor device 5628 is referred to for these semiconductor devices.

The semiconductor device 5629 has a shape with which the connection terminal 5629 can be inserted in the slot 5631 of the motherboard 5630, and the connection terminal 5629 functions as an interface for connecting the PC card 5621 and the motherboard 5630. An example of the standard for the semiconductor device 5629 is PCIe or the like.

The connection terminal 5623, the connection terminal 5624, and the connection terminal 5625 can serve as, for example, an interface for performing power supply, signal input, or the like to the PC card 5621. As another example, they can serve as an interface for outputting a signal computed by the PC card 5621. Examples of the standard for each of the connection terminal 5623, the connection terminal 5624, and the connection terminal 5625 include USB (Universal Serial Bus), SATA (Serial ATA), and SCSI (Small Computer System Interface). In the case where video signals are output from the connection terminal 5623, the connection terminal 5624, and the connection terminal 5625, an example of the standard therefor is HDMI (registered trademark) or the like.

The semiconductor device 5626 includes a terminal (not illustrated) for inputting and outputting signals, and when the terminal is inserted in a socket (not illustrated) of the board 5622, the semiconductor device 5626 and the board 5622 can be electrically connected to each other.

The semiconductor device 5627 includes a plurality of terminals, and when the terminals are reflow-soldered, for example, to wirings of the board 5622, the semiconductor device 5627 and the board 5622 can be electrically connected to each other. Examples of the semiconductor device 5627 include an FPGA, a GPU, and a CPU. As the semiconductor device 5627, the electronic component 730 can be used, for example.

The semiconductor device 5628 includes a plurality of terminals, and when the terminals are reflow-soldered, for example, to wirings of the board 5622, the semiconductor device 5628 and the board 5622 can be electrically connected to each other. An example of the semiconductor device 5628 is a memory device or the like. As the semiconductor device 5628, the electronic component 709 can be used, for example.

The large computer 5600 can also function as a parallel computer. When the large computer 5600 is used as a parallel computer, large-scale computation necessary for artificial intelligence learning and inference can be performed, for example.

### [Device for Space]

The semiconductor device of one embodiment of the present invention can be suitably used for space equipment, such as devices processing and storing information.

The semiconductor device of one embodiment of the present invention can include an OS transistor. A change in electrical characteristics of the OS transistor due to radiation irradiation is small. That is, the OS transistor is highly resistant to radiation, and thus can be suitably used even in an environment where radiation can enter. For example, the OS transistor can be suitably used in outer space.

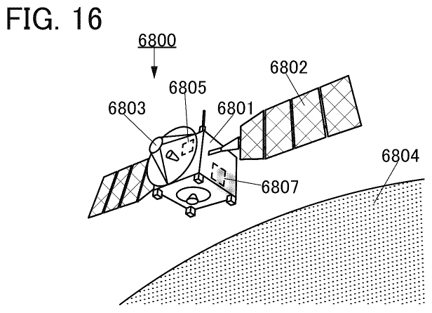

FIG. 16 illustrates an artificial satellite 6800 as an example of a device for space. The artificial satellite 6800 includes a body 6801, a solar panel 6802, an antenna 6803, a secondary battery 6805, and a control device 6807. Note that in FIG. 16, a planet 6804 in outer space is illustrated as an example. Note that outer space refers to, for example, space at an altitude greater than or equal to 100 km, and outer space described in this specification may include thermosphere, mesosphere, and stratosphere.

Although not illustrated in FIG. 16, a battery management system (also referred to as BMS) or a battery control circuit may be provided in the secondary battery 6805. The battery management system or the battery control circuit preferably includes an OS transistor, in which case low power consumption and high reliability are achieved even in outer space.

The amount of radiation in outer space is 100 or more times that on the ground. Note that examples of radiation include electromagnetic waves (electromagnetic radiation) typified by X-rays and gamma rays and particle radiation typified by alpha rays, beta rays, neutron beams, proton beams, heavy-ion beams, and meson beams.

When the solar panel 6802 is irradiated with sunlight, electric power required for the operation of the artificial satellite 6800 is generated. However, for example, in the situation where the solar panel is not irradiated with sunlight or the amount of sunlight with which the solar panel is irradiated is small, the amount of generated electric power is small. Accordingly, a sufficient amount of electric power required for the operation of the artificial satellite 6800 might not be generated. In order to operate the artificial satellite 6800 even with a small amount of generated electric power, the artificial satellite 6800 is preferably provided with the secondary battery 6805. Note that a solar panel is referred to as a solar cell module in some cases.

The artificial satellite 6800 can generate a signal. The signal is transmitted through the antenna 6803, and the signal can be received by a ground-based receiver or another artificial satellite, for example. When the signal transmitted by the artificial satellite 6800 is received, the position of a receiver that receives the signal can be measured. Thus, the artificial satellite 6800 can construct a satellite positioning system.

The control device 6807 has a function of controlling the artificial satellite 6800. The control device 6807 is formed with one or more selected from a CPU, a GPU, and a memory device, for example. Note that the semiconductor device of one embodiment of the present invention is suitably used for the control device 6807. A change in electrical characteristics due to radiation irradiation is smaller in an OS transistor than in a Si transistor. That is, the OS transistor has high reliability and thus can be suitably used even in an environment where radiation can enter.

The artificial satellite 6800 can be configured to include a sensor. For example, with a structure including a visible light sensor, the artificial satellite 6800 can have a function of sensing sunlight reflected by a ground-based object. Alternatively, with a structure including a thermal infrared sensor, the artificial satellite 6800 can have a function of sensing thermal infrared rays emitted from the surface of the earth. Thus, the artificial satellite 6800 can function as an earth observing satellite, for example.

Although the artificial satellite is described as an example of a device for space in this embodiment, one embodiment of the present invention is not limited thereto. The semiconductor device of one embodiment of the present invention can be suitably used for a device for space such as a spacecraft, a space capsule, or a space probe, for example.

As described above, an OS transistor has excellent effects of achieving a wide memory bandwidth and being highly resistant to radiation as compared with a Si transistor.

### [Data Center]

The semiconductor device of one embodiment of the present invention can be suitably used for, for example, a storage system in a data center or the like. Long-term management of data, such as guarantee of data immutability, is required for the data center. In the case where data is managed for a long term, it is necessary to increase the scale of the data center for installation of storages and servers for storing an enormous amount of data, stable electric power for data retention, cooling equipment for data retention, and the like.

With the use of the semiconductor device of one embodiment of the present invention for the storage system used in the data center, electric power required for data retention can be reduced and the size of a semiconductor device retaining data can be downsized. Thus, downsizing of the storage system, downsizing of the power supply for retaining data, downscaling of the cooling equipment, and the like can be achieved, for example. This can reduce the space of the data center.

In addition, since the semiconductor device of one embodiment of the present invention has low power consumption, heat generation from a circuit can be reduced. Accordingly, it is possible to reduce adverse effects of the heat generation on the circuit itself, a peripheral circuit, and a module. Furthermore, the use of the semiconductor device of one embodiment of the present invention can achieve a data center that operates stably even in a high temperature environment. Thus, the reliability of the data center can be increased.

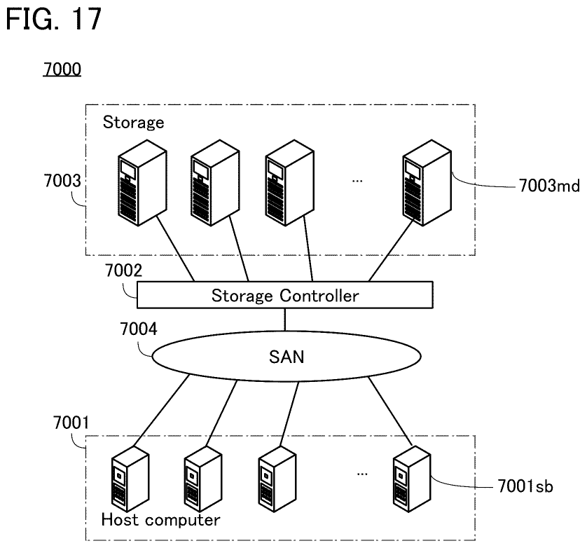

FIG. 17 illustrates a storage system that can be used in a data center. A storage system 7000 illustrated in FIG. 17 includes a plurality of servers 7001sb as a host 7001 (indicated as “Host Computer” in the diagram). The storage system 7000 includes a plurality of memory devices 7003md as a storage 7003 (indicated as “Storage” in the diagram). In the illustrated example, the host 7001 and the storage 7003 are connected to each other through a storage area network 7004 (indicated as “SAN” in the diagram) and a storage control circuit 7002 (indicated as “Storage Controller” in the diagram).

The host 7001 corresponds to a computer which accesses data stored in the storage 7003. The host 7001 may be connected to another host 7001 via a network.

The data access speed, i.e., the time taken for storing and outputting data, of the storage 7003 is shortened by using a flash memory, but is still considerably longer than the data access speed of a DRAM that can be used as a cache memory in a storage. In the storage system, in order to solve the problem of low access speed of the storage 7003, a cache memory is normally provided in a storage to shorten data storage and output.

The above-described cache memory is used in the storage control circuit 7002 and the storage 7003. The data transmitted between the host 7001 and the storage 7003 is stored in the cache memories in the storage control circuit 7002 and the storage 7003 and then output to the host 7001 or the storage 7003.

The use of an OS transistor as a transistor for storing data in the above-described cache memory to retain a potential based on data can reduce the frequency of refreshing, so that power consumption can be reduced. Furthermore, downscaling is possible by stacking memory cell arrays.

The use of the semiconductor device of one embodiment of the present invention for one or more selected from an electronic component, an electronic device, a large computer, space equipment, and a data center will produce an effect of reducing power consumption. While the demand for energy is expected to increase with higher performance or higher integration of semiconductor devices, the emission amount of greenhouse effect gases typified by carbon dioxide (CO₂) can be reduced with use of the semiconductor device of one embodiment of the present invention. Furthermore, the semiconductor device of one embodiment of the present invention has low power consumption and thus is effective as a global warming countermeasure.

The configuration, structure, method, or the like described in this embodiment can be used in combination with the configuration, structure, method, or the like described in the other embodiments and the like as appropriate.

### Supplementary Notes on Description in This Specification and the Like

The following are notes on the description of the above embodiments and the structures in the embodiments.
One embodiment of the present invention can be constituted by combining, as appropriate, the structure described in each embodiment with the structures described in the other embodiments. In addition, in the case where a plurality of structure examples are described in one embodiment, the structure examples can be combined as appropriate.
Note that content (or may be part of the content) described in one embodiment can be applied to, combined with, or replaced with another content (or may be part of the content) described in the embodiment and/or content (or may be part of the content) described in another embodiment or other embodiments.
Note that in each embodiment, a content described in the embodiment is a content described using a variety of diagrams or a content described with text disclosed in the specification.
Note that by combining a diagram (or may be part thereof) described in one embodiment with another part of the diagram, a different diagram (or may be part thereof) described in the embodiment, and/or a diagram (or may be part thereof) described in another embodiment or other embodiments, much more diagrams can be formed.
In addition, in this specification and the like, components are classified on the basis of the functions, and shown as blocks independent of one another in block diagrams. However, in an actual circuit or the like, it is difficult to separate components on the basis of the functions, and there is such a case where one circuit is associated with a plurality of functions or a case where a plurality of circuits are associated with one function. Thus, blocks in the block diagrams are not limited by the components described in this specification, and the description can be changed appropriately depending on the situation.
Furthermore, in the drawings, the size, the layer thickness, or the region is shown with given magnitude for description convenience. Thus, the size, the layer thickness, or the region is not limited to the illustrated scale. Note that the drawings are schematically shown for clarity, and embodiments of the present invention are not limited to shapes, values or the like shown in the drawings. For example, variations in a signal, a voltage, or a current due to noise, variations in a signal, a voltage, or a current due to difference in timing, or the like can be included.
In this specification and the like, expressions “one of a source and a drain” (or a first electrode or a first terminal) and “the other of the source and the drain” (or a second electrode or a second terminal) are used in the description of the connection relationship of a transistor. This is because the source and the drain of the transistor change depending on the structure, operating conditions, or the like of the transistor. Note that the source or the drain of the transistor can also be referred to as a source (or drain) terminal, a source (or drain) electrode, or the like as appropriate depending on the situation.
In addition, in this specification and the like, the term “electrode” or “wiring” does not limit the function of the component. For example, an “electrode” is used as part of a “wiring” in some cases, and vice versa. Furthermore, the term “electrode” or “wiring” also includes the case where a plurality of “electrodes” or “wirings” are formed in an integrated manner, for example.
Furthermore, in this specification and the like, “voltage” and “potential” can be interchanged with each other as appropriate. The voltage refers to a potential difference from a reference potential, and when the reference potential is ground voltage, for example, the voltage can be rephrased into the potential. The ground potential does not necessarily mean 0 V. Note that potentials are relative values, and a potential applied to a wiring or the like is sometimes changed depending on the reference potential.
In this specification and the like, the terms “film” and “layer” can be interchanged with each other depending on the case or situation. For example, the term “conductive layer” can be replaced with the term “conductive film” in some cases. As another example, the term “insulating film” can be changed into the term “insulating layer” in some cases.
In this specification and the like, a switch has a function of controlling whether current flows or not by being in a conduction state (on state) or a non-conduction state (off state). Alternatively, a switch has a function of selecting and switching a current path.
In this specification and the like, channel length refers to, for example, the distance between a source and a drain in a region where a semiconductor (or a portion where current flows in a semiconductor when a transistor is in an on state) and a gate overlap with each other or a region where a channel is formed in a top view of the transistor.
In this specification and the like, channel width refers to, for example, the length of a portion where a source and a drain face each other in a region where a semiconductor (or a portion where current flows in a semiconductor when a transistor is in an on state) and a gate electrode overlap with each other or a region where a channel is formed.
In this specification and the like, a node can be referred to as a terminal, a wiring, an electrode, a conductive layer, a conductor, an impurity region, or the like depending on a circuit structure, a device structure, or the like. Furthermore, a terminal, a wiring, or the like can be referred to as a node.
In this specification and the like, the expression “A and B are connected” means the case where A and B are electrically connected. Here, the expression “A and B are electrically connected” means connection that enables electrical signal transmission between A and B in the case where an object (that refers to an element such as a switch, a transistor element, or a diode, a circuit including the element and a wiring, or the like) exists between A and B. Note that the case where A and B are electrically connected includes the case where A and B are directly connected. Here, the expression “A and B are directly connected” means connection that enables electrical signal transmission between A and B through a wiring (or an electrode) or the like, not through the above object. In other words, direct connection refers to connection that can be regarded as the same circuit diagram when represented by an equivalent circuit.

### REFERENCE NUMERALS

10: semiconductor device, 20: base die, 21: clock signal generation circuit, 22: CPU, 23: cache memory, 30_1: die, 30_2: die, 30_3: die, 30_4: die, 31: GPU, 32: interface, 33: main memory, 34: interface, 35: peripheral circuit, 36: peripheral circuit, 37: bridge circuit, 38: peripheral circuit, 39: bridge circuit, 41: through electrode

1. A semiconductor device comprising:
a base die provided with a clock signal generation circuit and a first synchronous circuit; and
a plurality of dies provided to be stacked over the base die,
wherein the base die and the plurality of dies are electrically connected to each other via through electrodes provided in the plurality of dies,
wherein the plurality of dies each comprise a second synchronous circuit,
wherein the clock signal generation circuit is configured to generate a plurality of clock signals with different frequencies,
wherein the second synchronous circuit is a circuit operating by an input of any one of the clock signals with different frequencies to each of the plurality of dies, and
wherein the clock signals with different frequencies are supplied to the second synchronous circuits in the plurality of dies via the through electrodes.

2. The semiconductor device according to claim 1, wherein the first synchronous circuit is a CPU.

3. The semiconductor device according to claim 1, wherein the plurality of clock signals with different frequencies are signals generated on the basis of a reference frequency.

4. The semiconductor device according to claim 1, wherein a frequency of the clock signal supplied to the second synchronous circuit is lower than a frequency of the clock signal supplied to the first synchronous circuit.

5. The semiconductor device according to claim 1, wherein the through electrodes are electrically connected to each other via a metal bump provided between the plurality of dies.

6. The semiconductor device according to claim 1, wherein the second synchronous circuit comprises a transistor comprising an oxide semiconductor in a channel formation region.

7. The semiconductor device according to claim 6, wherein layers each comprising the transistor are provided to be stacked.

8. The semiconductor device according to claim 6, wherein the oxide semiconductor comprises In, Ga, and Zn
